(19) United States
(12) Patent Application Publication
(10) Pub. No.: US 2026/0088800 A1
(43) Pub. Date: Mar. 26, 2026

(54) ACOUSTIC WAVE DEVICE AND ACOUSTIC WAVE FILTER APPARATUS

(71) Applicant: Murata Manufacturing Co., Ltd., Nagaokakyo-shi (JP)

(72) Inventors: Akihiro IYAMA, Nagaokakyo-shi (JP); Yuta ISHII, Nagaokakyo-shi (JP); Katsuya DAIMON, Nagaokakyo-shi (JP)

(21) Appl. No.: 19/408,975

(22) Filed: Dec. 4, 2025

Related U.S. Application Data
(63) Continuation of application No. PCT/JP2024/021584, filed on Jun. 13, 2024.

(30) Foreign Application Priority Data
Jun. 13, 2023 (JP) 2023-097133

(51) Int. Cl. H03H 9/60; H03H 9/13

(52) U.S. Cl. CPC H03H 9/605; H03H 9/131; H03H 9/133

(57) ABSTRACT

An acoustic wave device includes a piezoelectric layer including first and second main surfaces, an IDT electrode on at least one of the first and second main surfaces and including electrode fingers arranged in a predetermined direction, and a support facing the second main surface and including an acoustic reflection portion toward the second main surface. At least one of a first electrode finger in an outermost portion and a second electrode finger internally adjacent to the first electrode finger differs from central electrode fingers inside the second electrode finger in at least one of a dimension in a direction orthogonal to an extension direction and an inter-center distance to an internally adjacent electrode finger, d/p is about 0.5 or less, where d denotes a thickness of the piezoelectric layer and p denotes the inter-center distance between adjacent electrode fingers.

### CROSS REFERENCE TO RELATED APPLICATIONS

This application claims the benefit of priority to Japanese Patent Application No. 2023-097133 filed on Jun. 13, 2023 and is a Continuation Application of PCT Application No. PCT/JP2024/021584 filed on Jun. 13, 2024. The entire contents of each application are hereby incorporated herein by reference.

### BACKGROUND OF THE INVENTION

### 1. Field of the Invention

The present invention relates to acoustic wave devices and acoustic wave filter apparatuses.

### 2. Description of the Related Art

Japanese Unexamined Patent Application and U.S. Pat. No. 11,349,450 describe acoustic wave devices.

The acoustic wave devices disclosed in Japanese Unexamined Patent Application and U.S. Pat. No. 11,349,450 have a possibility of a leakage of acoustic waves in an arrangement direction of electrode fingers.

### SUMMARY OF THE INVENTION

Example embodiments of the present invention provide acoustic wave devices and acoustic wave filter apparatuses each able to reduce or prevent a leakage of acoustic waves.

An acoustic wave device according to an example embodiment of the present invention includes a piezoelectric layer including a first main surface and a second main surface opposed to the first main surface, an IDT electrode on at least one of the first main surface and the second main surface of the piezoelectric layer and including a plurality of electrode fingers arranged in a predetermined direction, and a support facing the second main surface of the piezoelectric layer and including an acoustic reflection portion toward the second main surface of the piezoelectric layer. At least one of a first electrode finger located in an outermost portion in an arrangement direction of the plurality of electrode fingers among the plurality of electrode fingers and a second electrode finger internally adjacent to the first electrode finger in the arrangement direction differs from central electrode fingers arranged inside the second electrode finger in the arrangement direction in at least one of a dimension in a direction orthogonal or substantially orthogonal to an extension direction of the plurality of electrode fingers and an inter-center distance to an internally adjacent electrode finger in the arrangement direction, and d/p is about 0.5 or less, where d denotes a thickness of the piezoelectric layer and p denotes the inter-center distance between the adjacent electrode fingers.

An acoustic wave filter apparatus according to another example embodiment includes at least one resonator including an acoustic wave device according to an example embodiment of the present invention.

Acoustic wave devices and acoustic wave filter apparatuses according to example embodiments of the present invention are each able to reduce or prevent a leakage of acoustic waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view illustrating an acoustic wave device according to a first example embodiment of the present invention.

FIG. 2 is a sectional view taken along II-II′ in FIG. 1.

FIG. 3 is a schematic sectional view for explaining bulk waves of a thickness-shear primary mode propagating through a piezoelectric layer in the first example embodiment of the present invention.

FIG. 4 is a schematic sectional view for explaining amplitude directions of bulk waves of a thickness-shear primary mode propagating through a piezoelectric layer in the first example embodiment of the present invention.

FIG. 5 is an explanatory diagram showing an example of resonance characteristics of the acoustic wave device in the first example embodiment of the present invention.

FIG. 6 is an explanatory diagram showing a relationship between d/2p and a fractional bandwidth as a resonator, where p denotes an inter-electrode distance or an average value of inter-electrode distances between adjacent electrodes and d denotes an average thickness of the piezoelectric layer in the acoustic wave device in the first example embodiment of the present invention.

FIG. 7 is a plan view illustrating an example in which one electrode pair is provided in the acoustic wave device in the first example embodiment of the present invention.

FIG. 8 is a reference diagram showing an example of resonance characteristics of the acoustic wave device in the first example embodiment of the present invention.

FIG. 9 is an explanatory diagram showing a relationship between a fractional bandwidth and an amount of phase rotation of impedance of spurious emission normalized by about 180 degrees as the magnitude of spurious emission in a structure including a large number of acoustic wave resonators of the acoustic wave devices in the first example embodiment of the present invention.

FIG. 10 is an explanatory diagram illustrating a relationship among d/2p, a metallization ratio MR, and the fractional bandwidth.

FIG. 11 is an explanatory diagram showing a map of the fractional bandwidth with respect to Euler angles (0°, θ, ψ) of LiNbO₃ in a case where d/p is as close to zero as possible.

FIG. 12 is an enlarged sectional view of a region A in FIG. 2.

FIG. 13 is an explanatory diagram showing an example of admittance characteristics of the acoustic wave device according to the first example embodiment of the present invention.

FIG. 14 is an explanatory diagram showing a distribution of vibration modes in the acoustic wave device according to the first example embodiment of the present invention.

FIG. 15 is an explanatory diagram showing a distribution of vibration modes in the acoustic wave device according to a comparative example.

FIG. 16 is a sectional view illustrating an acoustic wave device according to a second example embodiment of the present invention.

FIG. 17 is an explanatory diagram showing an example of admittance characteristics of the acoustic wave device according to the second example embodiment of the present invention.

FIG. 18 is an explanatory diagram showing a distribution of vibration modes in the acoustic wave device according to the second example embodiment of the present invention.

FIG. 19 is an explanatory diagram showing a distribution of vibration modes in an acoustic wave device according to a comparative example.

FIG. 20 is a sectional view illustrating an acoustic wave device according to a first modification of the second example embodiment of the present invention.

FIG. 21 is an explanatory diagram showing an example of admittance characteristics of the acoustic wave device according to the first modification of the second example embodiment of the present invention.

FIG. 22 is a sectional view illustrating an acoustic wave device according to a second modification of the second example embodiment of the present invention.

FIG. 23 is an explanatory diagram showing an example of admittance characteristics of the acoustic wave device according to the second modification of the second example embodiment of the present invention.

FIG. 24 is a sectional view illustrating an acoustic wave device according to a third modification of the second example embodiment of the present invention.

FIG. 25 is an explanatory diagram showing an example of admittance characteristics of the acoustic wave device according to the third modification of the second example embodiment of the present invention.

FIG. 26 is a sectional view illustrating an acoustic wave device according to a third example embodiment of the present invention.

FIG. 27 is an explanatory diagram showing an example of admittance characteristics of the acoustic wave device according to the third example embodiment of the present invention.

FIG. 28 is a plan view illustrating an acoustic wave device in a fourth example embodiment of the present invention.

FIG. 29 is a sectional view taken along XXX-XXX′ in FIG. 28.

FIG. 30 is an enlarged sectional view illustrating a region A1 illustrated in FIG. 29.

FIG. 31 is an explanatory diagram showing an example of admittance characteristics of the acoustic wave device according to the fourth example embodiment of the present invention.

FIG. 32 is an explanatory diagram showing an example of admittance characteristics of an acoustic wave device according to a fourth modification of the fourth example embodiment of the present invention.

FIG. 33 is a sectional view illustrating an acoustic wave device according to a fifth modification of the fourth example embodiment of the present invention.

FIG. 34 is an explanatory diagram showing an example of admittance characteristics of the acoustic wave device according to the fifth modification of the fourth example embodiment of the present invention.

FIG. 35 is a circuit diagram illustrating an acoustic wave filter apparatus according to a fifth example embodiment of the present invention.

FIG. 36 is a sectional view illustrating an acoustic wave device according to a sixth example embodiment of the present invention.

FIG. 37 is a sectional view illustrating an acoustic wave device according to a seventh example embodiment of the present invention.

FIG. 38 is an explanatory diagram showing an example of admittance characteristics of an acoustic wave device according to an eighth example embodiment of the present invention.

FIG. 39 is an explanatory diagram showing an example of an impedance phase in a high-order mode.

FIG. 40 is a plan view illustrating an IDT electrode of an acoustic wave device according to a ninth example embodiment of the present invention.

FIG. 41 is an explanatory diagram illustrating an inter-electrode pitch Pₙ in the acoustic wave device according to the ninth example embodiment of the present invention.

FIG. 42 is an explanatory diagram showing an impedance phase of an acoustic wave device according to a comparative example 1.

FIG. 43 is an explanatory diagram showing impedance phases at about 5102 MHz in the acoustic wave devices according to the ninth example embodiment and the comparative examples 1 and 2.

FIG. 44 is a plan view illustrating an IDT electrode of an acoustic wave device according to a tenth example embodiment of the present invention.

FIG. 45 is an explanatory diagram showing electrode widths wₙ in the acoustic wave device according to the tenth example embodiment of the present invention.

FIG. 46 is an explanatory diagram showing impedance phases at about 5102 MHz in the acoustic wave devices according to the tenth example embodiment and comparative examples 1 and 3.

### DETAILED DESCRIPTION OF THE EXAMPLE EMBODIMENTS

Hereinafter, example embodiments of the present disclosure will be described in detail with reference to the drawings. The present invention is not limited by these example embodiments. All of the example embodiments described in the present disclosure are illustrative. In the second and subsequent example embodiments, where some portions of a structure may be replaced or combined with some portions in any of the other example embodiments, descriptions of common matters with a first example embodiment will be omitted, and only different points will be explained. In particular, the same or similar advantageous effects due to the same or similar structures will not be described redundantly in each example embodiment. Furthermore, in the present disclosure, in a case where a notation X°+Y° is used to express Euler angles or cut angles, the notation means that the angle is equal to X°-Y° or more and X°+Y° or less.

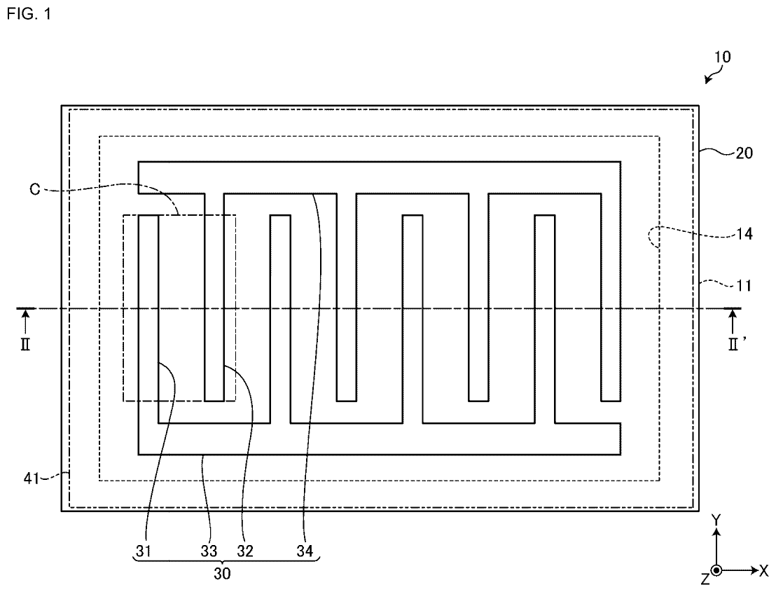

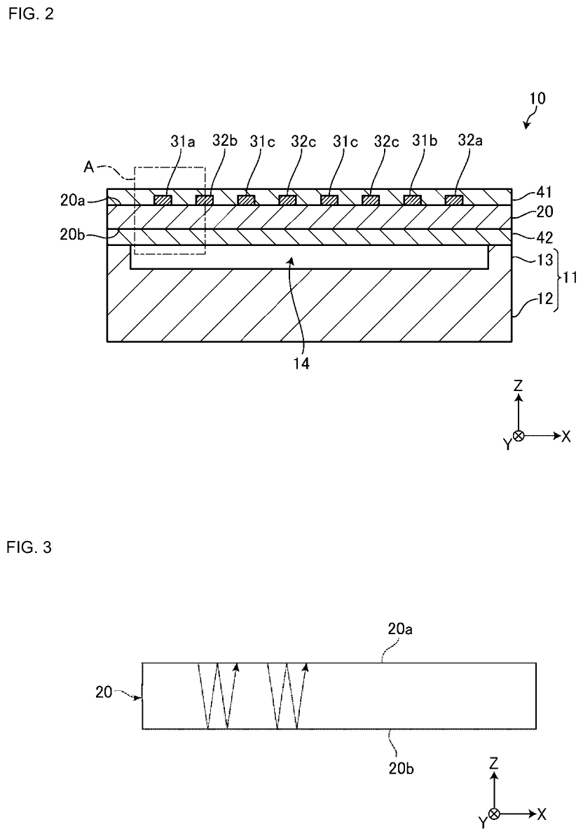

FIG. 1 is a plan view illustrating an acoustic wave device in a first example embodiment of the present invention. FIG. 2 is a sectional view taken along II-II′ in FIG. 1. In FIG. 1, a first protective film 41 is indicated by a dash-double-dot line.

As illustrated in FIGS. 1 and 2, an acoustic wave device 10 according to the first example embodiment includes a piezoelectric layer 20, an IDT electrode 30, a supporting substrate 11, the first protective film 41, and a second protective film 42. As illustrated in FIG. 2, in the acoustic wave device 10, the second protective film 42, the piezoelectric layer 20, the IDT electrode 30, and the first protective film 41 are stacked in this order on the supporting substrate 11.

The piezoelectric layer 20 has a flat plate shape including a first main surface 20a and a second main surface 20b on the opposite side of the first main surface 20a. The piezoelectric layer 20 is made of, for example, lithium niobate (LiNbO₃). Alternatively, the piezoelectric layer 20 may be made of, for example, lithium tantalate (LiTaO₃). Cut angles of LiNbO₃ or LiTaO₃ are Z-cut in the first example embodiment. The cut angles of LiNbO₃ or LiTaO₃ may be rotated Y-cut or X-cut. Preferably, for example, the propagation directions are Y propagation and X propagation about ±30°. Preferably, for example, the piezoelectric layer 20 includes lithium niobate (LiNbO₃) or lithium tantalate (LiTaO₃) and is 120°±10° rotated Y-cut or 90°±10° rotated Y-cut. Here, 120°±10° includes the range of, for example, about 120°−10° or more to about 120°+10° or less, and 90°+10° includes the range of about 90°−10° or more to about 90°+10° or less.

The thickness of the piezoelectric layer 20 is not particularly limited but is, for example, preferably about 50 nm or more and about 1000 nm or less in order to effectively excite a thickness-shear primary mode. The film thickness of the piezoelectric layer 20 according to the first example embodiment is, for example, about 180 nm.

The IDT (Interdigital Transducer) electrode 30 is provided on the first main surface 20a of the piezoelectric layer 20. As illustrated in FIG. 1, the IDT electrode 30 includes electrode fingers 31 and 32 and busbar electrodes 33 and 34. Multiple electrode fingers 31 extend in a Y direction, and one end portions thereof in the extension direction are connected to the busbar electrode 33. Multiple electrode fingers 32 extend in the Y direction, and the other end portions thereof in the extension direction are connected to the busbar electrode 34. The multiple electrode fingers 31 and the multiple electrode fingers 32 are alternately arranged in the X direction at certain intervals. The busbar electrode 33 and the busbar electrode 34 each extend in the X direction and are spaced apart from each other in the Y direction. The multiple electrode fingers 31 and 32 are arranged between the busbar electrodes 33 and 34.

The following description will be provided assuming that the thickness direction of the piezoelectric layer 20 is the Z direction, the extension direction of the electrode fingers 31 and 32 is the Y direction, and the arrangement direction of the electrode fingers 31 and 32 is the X direction. Moreover, in the following description, plan view shows an arrangement relationship perpendicular seen from the direction or substantially perpendicular to the first main surface 20a of the piezoelectric layer 20.

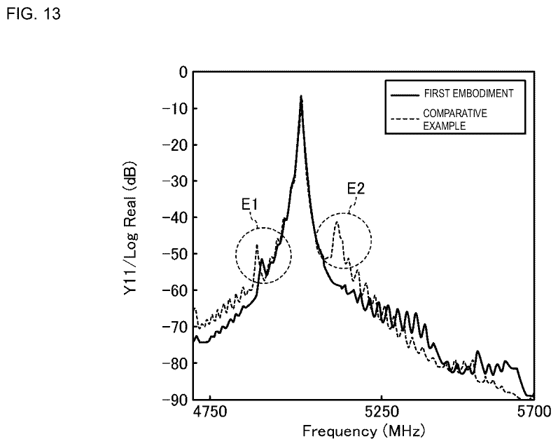

The distance between the widthwise centers of the electrode fingers 31 and 32 adjacent to each other in the X direction (hereinafter referred to as an inter-electrode pitch) is, for example, preferably in a range of about 1 μm or more to about 10 μm or less. The inter-electrode pitch is the distance connecting the center of the width dimension of the electrode finger 31 in the direction orthogonal or substantially orthogonal to the extension direction of the electrode finger 31 and the center of the width dimension of the electrode finger 32 in the direction orthogonal or substantially orthogonal to the extension direction of the electrode finger 32. Moreover, the widths of the electrode fingers 31 and 32 (hereinafter referred to as electrode widths), specifically, the dimensions of the electrode fingers 31 and 32 in the direction orthogonal or substantially orthogonal to the extension direction are, for example, preferably in a range of about 150 nm or more to about 1000 nm or less. The inter-electrode pitches and the electrode widths of the electrode fingers 31 and 32 will be described in detail later with reference to FIGS. 12 and 13.

Moreover, when at least one type of the electrode fingers 31 and the electrode fingers 32 includes multiple electrode fingers (there are 1.5 or more electrode pairs, where one electrode pair is composed of one electrode finger 31 and one electrode finger 32), the inter-electrode pitch between the electrode finger(s) 31 and the electrode finger(s) 32 means an average value of the inter-center distances between the electrode finger(s) 31 and the electrode finger(s) 32 adjacent to each other in the 1.5 or more pairs of the electrode finger(s) 31 and the electrode finger(s) 32.

In addition, since the first example embodiment includes the Z-cut piezoelectric layer, a direction orthogonal or substantially orthogonal to the extension direction of the electrode fingers 31 and the electrode fingers 32 is a direction orthogonal or substantially orthogonal to a polarization direction of the piezoelectric layer 20. This does not apply in a case where a piezoelectric material with different cut angles is used as the piezoelectric layer 20. Here, “orthogonal” is not limited to being strictly orthogonal, but may also be approximately orthogonal (the angle formed by the direction orthogonal to the extension direction of the electrode fingers 31 and 32 and the polarization direction is, for example, about) 90°±10°.

The IDT electrode 30 (the electrode fingers 31 and 32 and the busbar electrodes 33 and 34) is made of an appropriate metal or alloy such as, for example, Al or an AlCu alloy. In the first example embodiment, for example, the IDT electrode 30 has a structure in which an Al film is stacked on a titanium (Ti) film. Here, an adhesion layer other than the Ti film may be used.

More specifically, an electrode structure of the IDT electrode 30 includes a multilayer film of Ti/AlCu/Ti/AlCu stacked from the piezoelectric layer 20 side, and their respective film thicknesses are about 12 nm/about 70 nm/about 18 nm/about 12 nm. In addition, the total number of the electrode fingers 31 and 32 in the IDT electrode 30 is, for example, 51. The inter-electrode pitches between the electrode fingers 31 and 32 are, for example, about 2.38 μm and the electrode width of each of the electrode fingers 31 and 32 is, for example, about 0.6 μm.

Here, an intersecting region C (excitation region) illustrated in FIG. 1 is a region where the electrode fingers 31 and the electrode fingers 32 overlap each other as viewed in the X direction. The length of the intersecting region C is a dimension of the intersecting region C in the extension direction of the electrode fingers 31 and the electrode fingers 32. In the present example embodiment, the length of the intersecting region C is, for example, about 40 μm.

For driving, an alternating voltage is applied across the multiple electrode fingers 31 and the multiple electrode fingers 32. More specifically, the alternating voltage is applied across the busbar electrode 33 and the busbar electrode 34. This makes it possible to obtain resonance characteristics by utilizing bulk waves of the thickness-shear primary mode excited in the piezoelectric layer 20.

In addition, in the acoustic wave device 10, d/p is, for example, about 0.5 or less, where d denotes the thickness of the piezoelectric layer 20 and p denotes the inter-electrode pitches between the electrode fingers 31 and the electrode fingers 32 in multiple pairs. Therefore, the bulk waves of the thickness-shear primary mode are excited effectively, and appropriate resonance characteristics can be obtained. More preferably, for example, d/p is about 0.24 or less, and more appropriate resonance characteristics can be obtained in this case.

Since the acoustic wave device 10 in the first example embodiment has the above structure, even if the number of pairs of the electrode fingers 31 and the electrode fingers 32 is reduced in an attempt to reduce the size, the Q factor is less likely to decrease. This is because the acoustic wave device 10 is a resonator that does not include reflectors on both sides and has a low propagation loss. Moreover, the reason why the above reflectors are unnecessary is use of the bulk waves of the thickness-shear primary mode.

The first protective film 41 is provided on the first main surface 20a of the piezoelectric layer 20 and covers the IDT electrode 30. The second protective film 42 is provided on the second main surface 20b of the piezoelectric layer 20. The first protective film 41 and the second protective film 42 are made of, for example, silicon oxide (SiO₂). The first protective film 41 and the second protective film 42 may be made of an appropriate insulating material such as, for example, silicon nitride or alumina other than silicon oxide. A film thickness t1 of the first protective film 41 and a film thickness t2 of the second protective film 42 are, for example, both about 142 nm. The film thickness t1 of the first protective film 41 refers to the maximum value of the total distance from the surface of the first protective film 41 on the first main surface 20a side to the surface of the first protective film 41 on the side opposite to the first main surface 20a in the intersecting region C. The film thickness t2 of the second protective film 42 refers to the maximum value of the total distance from the surface of the second protective film 42 on the second main surface 20b side to the surface of the second protective film 42 on the side opposite to the second main surface 20b in the intersecting region C. It is sufficient to provide at least one of the first protective film 41 and the second protective film 42. For example, in a possible structure, the first protective film 41 is provided and the second protective film 42 is not provided.

The supporting substrate 11 (support) is arranged so as to face the second main surface 20b of the piezoelectric layer 20. The supporting substrate 11 includes a cavity portion 14 (hollow portion) on the surface facing the second main surface 20b of the piezoelectric layer 20. More specifically, the supporting substrate 11 includes a bottom portion 12 and a frame-shaped wall portion 13 provided on an upper surface of the bottom portion 12. The cavity portion 14 is provided in a space surrounded by the bottom portion 12 and the wall portion 13. The piezoelectric layer 20 is stacked on an upper surface of the wall portion 13 of the supporting substrate 11 with the second protective film 42 interposed in between. In this way, the acoustic wave device 10 has a membrane structure in which the cavity portion 14 (hollow portion) is provided on the second main surface 20b side of the piezoelectric layer 20. Here, the support may include the supporting substrate 11 and an intermediate (insulation) layer. Specifically, the supporting substrate 11 may be stacked indirectly on the second main surface 20b of the piezoelectric layer 20. In this case, the supporting substrate 11 and the intermediate layer have a frame shape, thus defining the cavity portion 14. Instead, the intermediate layer may be provided with a recessed portion which defines the cavity portion 14.

The cavity portion 14 is provided so as not to interfere with vibrations of the intersecting region C of the piezoelectric layer 20. The second protective film 42 is provided so as to cover an opening of the cavity portion 14. However, as described above, the second protective film 42 does not have to be provided. In this case, the supporting substrate 11 may be stacked directly on the second main surface 20b of the piezoelectric layer 20. Instead, the second protective film 42 may be provided in a region between the upper surface of the wall portion 13 and the second main surface 20b of the piezoelectric layer 20, excluding a region covering the cavity portion 14.

The supporting substrate 11 is made of, for example, silicon (Si). The crystal orientation of the Si surface on the piezoelectric layer 20 side may be (100), (110), or (111). Si preferably having a high resistivity of, for example, about 4 kΩ or more is preferable. Instead, the supporting substrate 11 may also be made of an appropriate insulating material or semiconductor material. Examples of a material usable for the supporting substrate 11 include piezoelectric materials such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, dielectrics such as diamond or glass, semiconductors such as gallium nitride, or the like.

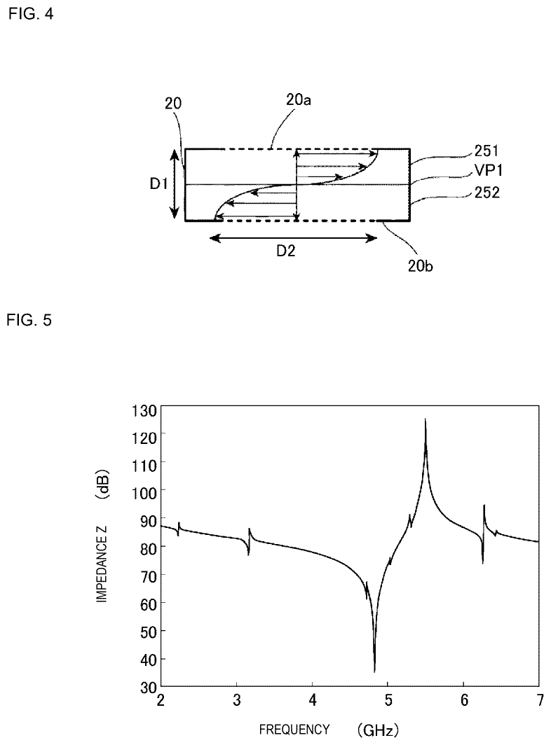

FIG. 3 is a schematic sectional view for explaining bulk waves of the thickness-shear primary mode propagating through the piezoelectric layer in the first example embodiment. FIG. 4 is a schematic sectional view for explaining amplitude directions of the bulk waves of the thickness-shear primary mode propagating through the piezoelectric layer in the first example embodiment.

As illustrated in FIG. 3, in the acoustic wave device 10 in the first example embodiment, vibration displacement is in a thickness-shear direction, so that the waves propagate and resonate mostly in the direction connecting the first main surface 20a and the second main surface 20b of the piezoelectric layer 20, in short, in the Z direction. In other words, an X-direction component of the waves is significantly smaller than a Z-direction component thereof. Then, since the resonance characteristics can be obtained by this wave propagation in the Z direction, no reflectors are needed. Therefore, no propagation loss occurs in propagation through the reflectors. Accordingly, even if the number of pairs of the electrode fingers 31 and the electrode fingers 32 is reduced in an attempt to reduce the size, the Q factor is less likely to decrease.

As illustrated in FIG. 4, the amplitude directions of the bulk waves of the thickness-shear primary mode are opposite between a first region 251 included in the intersecting region C and a second region 252 included in the intersecting region C of the piezoelectric layer 20 (see FIG. 1). FIG. 4 schematically illustrates the bulk waves in a case where a voltage that provides a higher potential to the electrode finger 32 than to the electrode finger 31 is applied across the electrode finger 31 and the electrode finger 32. Here, a virtual plane VP1 is a plane being orthogonal to the thickness direction of the piezoelectric layer 20 and partitioning the piezoelectric layer 20 into two regions. The first region 251 is a region between the virtual plane VP1 and the first main surface 20a in the intersecting region C. The second region 252 is a region between the virtual plane VP1 and the second main surface 20b in the intersecting region C.

In the acoustic wave device 10, at least one electrode pair of the electrode finger 31 and the electrode finger 32 is provided. Since the acoustic wave device 10 is not intended to propagate waves in the X direction, multiple electrode pairs of the electrode finger 31 and the electrode finger 32 are not necessarily needed. In other words, it is sufficient to provide at least one electrode pair.

For example, the electrode finger 31 is an electrode coupled to a hot potential, whereas the electrode finger 32 is an electrode coupled to a ground potential. Instead, the electrode finger 31 may be coupled to the ground potential, and the electrode finger 32 may be coupled to the hot potential. In the first example embodiment, at least one electrode pair includes an electrode coupled to the hot potential and an electrode coupled to the ground potential and does not include a floating electrode.

FIG. 5 is an explanatory diagram showing an example of resonance characteristics of the acoustic wave device in the first example embodiment. Design parameters of the acoustic wave device 10 for obtaining the resonance characteristics shown in FIG. 5 are as follows:
Piezoelectric Layer 20: LiNbO₃ with Euler angles (0°, 0°, 90°)
Thickness of Piezoelectric Layer 20: about 400 nm
Length of Intersecting region C: about 40 μm
Number of Electrode Pairs of Electrode Fingers 31 and 32: 21 pairs
Inter-Electrode Pitches between Electrode Fingers 31 and 32: about 3 μm
Widths of Electrode Fingers 31 and 32: about 500 nm
d/p: about 0.133
First Protective Film 41 and Second Protective Film 42: about 1-μm Thick Silicon Dioxide Film
Supporting Substrate 11: Si

As is clear from FIG. 5, appropriate resonance characteristics with a fractional bandwidth of about 12.5% are obtained despite the absence of reflectors.

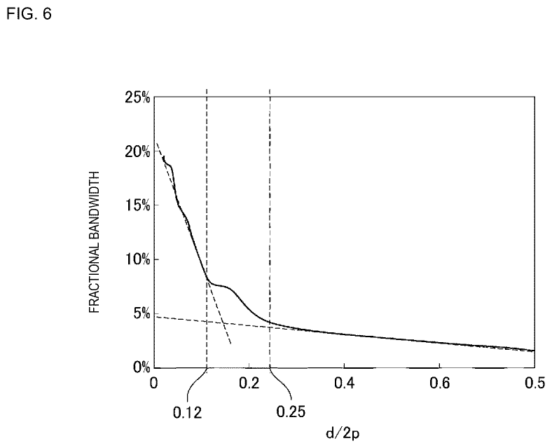

Here, in the case where d denotes the thickness of the piezoelectric layer 20 and p denotes the inter-electrode pitch between the electrode fingers 31 and 32, d/p is, for example, about 0.5 or less and more preferably about 0.24 or less in the first example embodiment. The reason why will be described with reference to FIG. 6.

FIG. 6 is an explanatory diagram showing a relationship between d/2p and a fractional bandwidth as a resonator in the acoustic wave device in the first example embodiment, where p denotes an inter-center distance or an average value of inter-center distances between adjacent electrodes and d denotes an average thickness of the piezoelectric layer. In FIG. 6, multiple acoustic wave devices were obtained in the same manner as the acoustic wave device for obtaining the resonance characteristics shown in FIG. 5, except that d/2p was changed.

As shown in FIG. 6, if d/2p exceeds about 0.25, i.e., d/p>about 0.5, the fractional bandwidth is less than about 5% no matter how d/p is adjusted. In contrast, if d/2p≤about 0.25, i.e., d/p≤about 0.5, changing d/p to this range makes it possible to obtain a fractional bandwidth of about 5% or more, in other words, to construct a resonator with a high coupling coefficient. Moreover, if d/2p is about 0.12 or less, i.e., d/p is about 0.24 or less, the fractional bandwidth can be increased to about 7% or more. In addition, adjusting d/p within this range makes it possible to obtain a resonator with an even wider fractional bandwidth and therefore realize a resonator with an even higher coupling coefficient. Therefore, setting d/p to about 0.5 or less makes it possible to construct a resonator with a high coupling coefficient while using the bulk waves of the aforementioned thickness-shear primary mode.

Here, if the piezoelectric layer 20 varies in thickness, the average value of the thicknesses may be used as the thickness d of the piezoelectric layer 20.

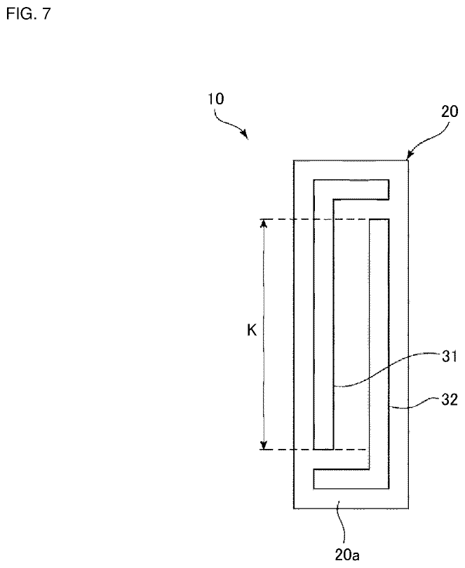

FIG. 7 is a plan view illustrating an example in which one electrode pair is provided in the acoustic wave device in the first example embodiment. In the acoustic wave device 10, one electrode pair including the electrode finger 31 and the electrode finger 32 is provided on the first main surface 20a of the piezoelectric layer 20. In FIG. 7, K denotes an intersecting width. As described above, the acoustic wave device 10 may include only one electrode pair. Even in this case, as long as d/p is about 0.5 or less as described above, the acoustic wave device 10 can effectively excite bulk waves of the thickness-shear primary mode.

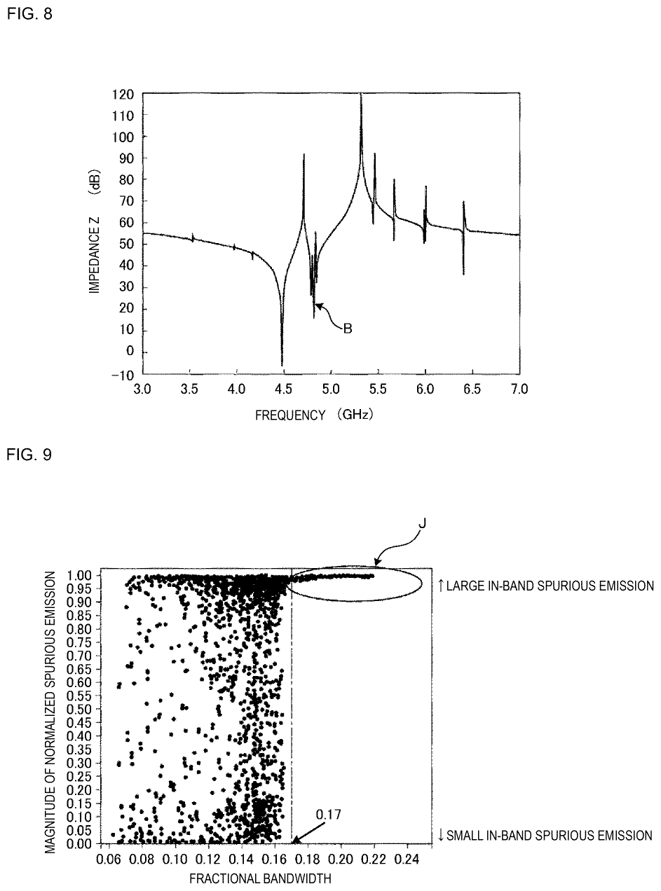

In the acoustic wave device 10, for example, it is preferable that a metallization ratio MR of the above adjacent electrode fingers 31 and 32 to the intersecting region C satisfy MR≤about 1.75 (d/p)+0.075. In this case, spurious emission can be effectively reduced. This will be described with reference to FIGS. 8 and 9.

FIG. 8 is a reference diagram showing an example of the resonance characteristics of the acoustic wave device in the first example embodiment. As illustrated in FIG. 8, spurious emission indicated by an arrow B appears between a resonant frequency and an anti-resonant frequency. Here, for example, d/p was set to about 0.08 and the Euler angles of LiNbO₃ were set to (0°, 0°, 90°). The above metallization ratio MR was set to, for example, about 0.35.

The metallization ratio MR will be described with reference to FIG. 1. Focusing on one pair of the electrode finger 31 and the electrode finger 32 in the electrode structure in FIG. 1, it is assumed that only this one pair of the electrode finger 31 and the electrode finger 32 is provided. In this case, a section surrounded by a dash-dot line is the intersecting region C. As the electrode finger 31 and the electrode finger 32 are viewed in the direction orthogonal to the extension direction of the electrode finger 31 and the electrode finger 32, in other words, in the facing direction, this intersecting region C includes a region of the electrode finger 31 overlapping the electrode finger 32, a region of the electrode finger 32 overlapping the electrode finger 31, and a region where the electrode finger 31 and the electrode finger 32 overlap each other in a region between the electrode finger 31 and the electrode finger 32. Then, the metallization ratio MR is a ratio of the area of the electrode finger 31 and the electrode finger 32 of the intersecting region C to the area of the intersecting region C. In sum, the metallization ratio MR is a ratio of the area of a metallization portion to the area of the intersecting region C.

In a case where multiple pairs of the electrode fingers 31 and the electrode fingers 32 are provided, a ratio of area of all of metallization portions included in the intersecting region C to the total area of the intersecting region C may be determined as MR.

FIG. 9 is an explanatory diagram showing a relationship between a fractional bandwidth and an amount of phase rotation of impedance of spurious emission normalized by about 180 degrees as a magnitude of the spurious emission in a structure including a large number of acoustic wave resonators of the acoustic wave devices in the first example embodiment. The fractional bandwidth was adjusted by variously changing the film thickness of the piezoelectric layer 20 and the dimensions of the electrode fingers 31 and the electrode fingers 32. Although FIG. 9 shows the result in the case where the piezoelectric layer 20 made of Z-cut LiNbO₃ was used, a similar tendency will also be obtained even in a case where the piezoelectric layer 20 with other cut angles is used.

In a region surrounded by an ellipse J in FIG. 9, the spurious emission is as large as about 1.0. As is clear from FIG. 9, if the fractional bandwidth exceeds about 0.17, i.e., exceeds about 17%, large spurious emission at a spurious level of about 1 or more appears within a pass band, no matter how the parameters that define the fractional bandwidth are changed. In other words, the large spurious emission indicated by the arrow B appears in the band as in the resonance characteristics shown in FIG. 8. Therefore, the fractional bandwidth is, for example, preferably about 17% or less. In this case, spurious emission can be reduced by adjusting the film thickness of the piezoelectric layer 20, the dimensions of the electrode finger 31 and the electrode finger 32, and so forth.

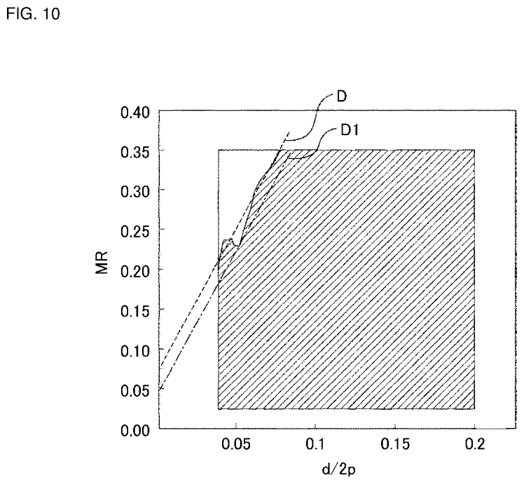

FIG. 10 is an explanatory diagram showing a relationship among d/2p, the metallization ratio MR, and the fractional bandwidth. Regarding the acoustic wave device 10 in the first example embodiment, various acoustic wave devices 10 different in d/2p and MR were provided and their fractional bandwidths were measured. In FIG. 10, a hatched portion to the right of a broken line D is a region where the fractional bandwidth is about 17% or less. The boundary between this hatched region and the unhatched region is expressed as MR=about 3.5 (d/2p)+0.075. This is converted to MR=about 1.75 (d/p)+0.075. Accordingly, for example, it is preferable that MR≤about 1.75 (d/p)+0.075. In this case, it is easy to set the fractional bandwidth to about 17% or less. A more preferable region is a region to the right of a dash-dot line D1 representing MR=about 3.5 (d/2p)+0.05 in FIG. 10. In other words, if MR≤about 1.75 (d/p)+0.05, the fractional bandwidth can be surely set to about 17% or less.

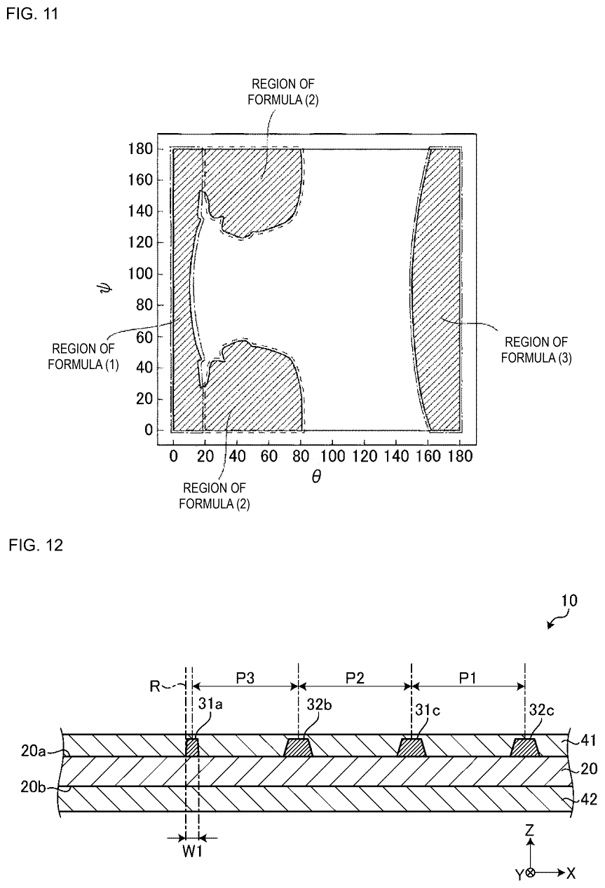

FIG. 11 is an explanatory diagram showing a map of the fractional bandwidth with respect to the Euler angles (0°, θ, ψ) of LiNbO₃ in a case where d/p is as close to zero as possible. In FIG. 11, hatched portions are regions where the fractional bandwidth of at least 5% or more is obtained. The ranges of the regions are approximated to ranges specified by Formulas (1), (2), and (3) below:

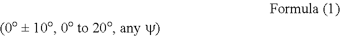

(0°±10°, 20° to 80°, 0° to 60°(1−(θ−50)²/900)^{1/2}) or

(0°±10°, 20° to 80°, {180°−60°(1−(θ−50)²/900)^{1/2}} to 180°) . . . Formula (2)

(0°±10°, {180°−30°(1−(ψ−90)²/8100)^{1/2}} to 180°, any ψ) . . . Formula (3)

Therefore, the range of the Euler angles of Formula (1), Formula (2) or Formula (3) above is preferable because the fractional bandwidth can be made sufficiently wide.

Next, the structure of the electrode fingers 31 and 32 will be described in detail. FIG. 12 is an enlarged sectional view of a region A in FIG. 2. In FIG. 12, description will be provided about a first electrode finger 31a located in the outermost portion in the arrangement direction of the multiple electrode fingers 31 and 32 and a second electrode finger 32b adjacent to the first electrode finger 31a. Here the structure of the first and second electrode fingers 31a and 32a is linearly symmetrical with a structure of a third electrode finger 32a located in the outermost portion opposite to the first electrode finger 31a and a fourth electrode finger 31b adjacent to the third electrode finger 32a. Description about the first electrode finger 31a may also apply to the description about the third electrode finger 32a, and description about the second electrode finger 32b may also apply to the description about the fourth electrode finger 31b.

In the following description, among the multiple electrode fingers 31 and 32, electrode fingers other than the first electrode finger 31a, the second electrode finger 32b, the third electrode finger 32a, and the fourth electrode finger 31b will be referred to as central electrode fingers 31c and 32c in some cases. Specifically, the central electrode fingers 31c and 32c are located in an internal portion between the first and second electrode fingers 31a and 32b and the third and fourth electrode fingers 32a and 31b in the arrangement direction, and are the electrode fingers 31 and 32 located in a central portion in the arrangement direction. In the following description, in a case where there is no need to distinguish between the first electrode finger 31a, the second electrode finger 32b, the third electrode finger 32a, the fourth electrode finger 31b, and the central electrode fingers 31c and 32c, they will be simply referred to as the electrode fingers 31 and 32. In the following description, the inter-electrode pitch between the first electrode finger 31a and the second electrode finger 32b is denoted as P3, the inter-electrode pitch between the second electrode finger 32b and its adjacent central electrode finger 31c is denoted as P2, and the inter-electrode pitch between adjacent two of the multiple central electrode fingers 31c and 32c is denoted as P1. In the present example embodiment, all the inter-electrode pitches between the adjacent electrode fingers of the multiple central electrode fingers 31c and 32c are equal to P1.

As illustrated in FIG. 12, the electrode width of the first electrode finger 31a is smaller than the electrode widths of the second electrode finger 32b and the central electrode fingers 31c and 32c. Moreover, the inter-electrode pitch P3 is smaller than the inter-electrode pitches P1 and P2. In the present example embodiment, the electrode width W1 of the first electrode finger 31a is, for example, about 0.3 μm, and the electrode widths of the second electrode finger 32b and the central electrode fingers 31c and 32c are, for example, about 0.6 μm. The inter-electrode pitch P3 is, for example, about 2.23 μm and the inter-electrode pitches P1 and P2 are, for example, about 2.38 μm.

In this way, the electrode width W1 and the inter-electrode pitch P3 of the first electrode finger 31a located in the outermost portion in the arrangement direction are different from the electrode width and the inter-electrode pitch P1 of the central electrode fingers 31c and 32c. Thus, in a region overlapping the first electrode finger 31a, an acoustic impedance different from those in regions overlapping the other electrode fingers occurs. As a result, an acoustic reflection surface R is provided at an outer end portion of the first electrode finger 31a in the arrangement direction of the multiple electrode fingers 31 and 32.

Thus, acoustic waves excited in the piezoelectric layer 20 are reflected by the acoustic reflection surface R, and therefore the acoustic wave device 10 can reduce or prevent a leakage of acoustic waves in the arrangement direction of the multiple electrode fingers 31 and 32.

FIG. 13 is an explanatory diagram showing an example of admittance characteristics of the acoustic wave device according to the first example embodiment. More specifically, FIG. 13 is the explanatory diagram showing a real part of admittance, i.e., a conductance component, of the acoustic wave device according to the first example embodiment. The admittance characteristics shown in FIG. 13 show a simulation result of the admittance characteristics of the acoustic wave device 10 according to the first example embodiment. In addition, FIG. 13 also shows a simulation result of admittance characteristics of an acoustic wave device according to a comparative example. The comparative example is an acoustic wave device including the electrode fingers 31 and 32 all having equal or substantially equal electrode widths and equal or substantially equal inter-electrode pitches as compared to the first example embodiment.

As shown in FIG. 13, in the acoustic wave device according to the comparative example, ripples occur in frequency domains different from a resonant frequency. In the comparative example, large ripples indicated by dotted lines E1 and E2 occur, in particular. In contrast, in the acoustic wave device 10 according to the first example embodiment in which the electrode width W1 and the inter-electrode pitch P3 of the first electrode finger 31a located in the outermost portion in the arrangement direction are different from the electrode width and the inter-electrode pitch P1 of the central electrode fingers 31c and 32c, it is seen that the ripples indicated by the dotted lines E1 and E2 are reduced or prevented compared to the comparative example. The acoustic wave device 10 according to the first example embodiment has a narrower peak width related to the resonant frequency than the acoustic wave device according to the comparative example, which means that a propagation loss is reduced or prevented and a leakage of acoustic waves is reduced or prevented.

In the first example embodiment shown in FIG. 12, the structure is illustrated in which the electrode width of one first electrode finger 31a is smaller than the electrode width of the other electrode fingers 31 and 32, but the structure is not limited to this. Another structure may be possible in which the electrode widths of multiple electrode fingers 31 and 32 located in the outermost portion in the arrangement direction of the multiple electrode fingers 31 and 32 are smaller than the electrode widths of the other electrode fingers 31 and 32 located in the central portion. Similarly, another structure may be possible in which the inter-electrode pitches P between three or more electrode fingers 31 and 32 located in the outermost portion in the arrangement direction of the multiple electrode fingers 31 and 32 are smaller than the inter-electrode pitches P between the other electrode fingers 31 and 32 located in the central portion.

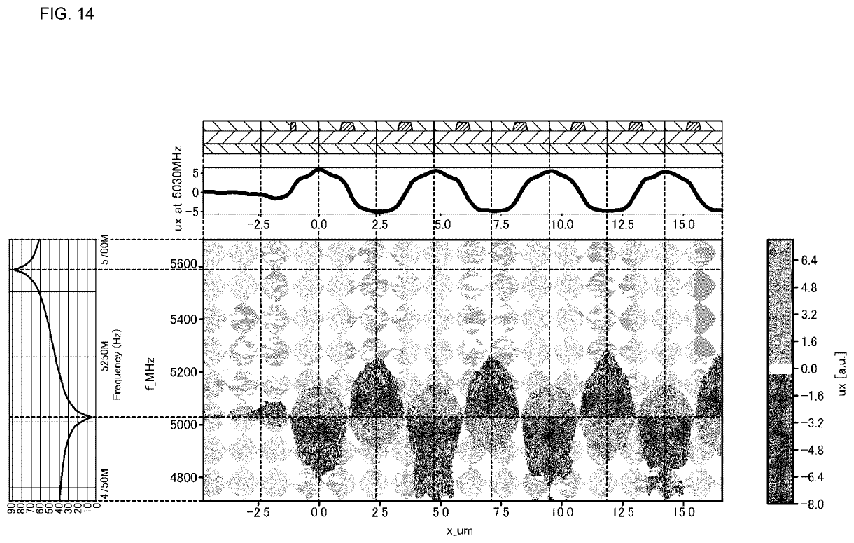

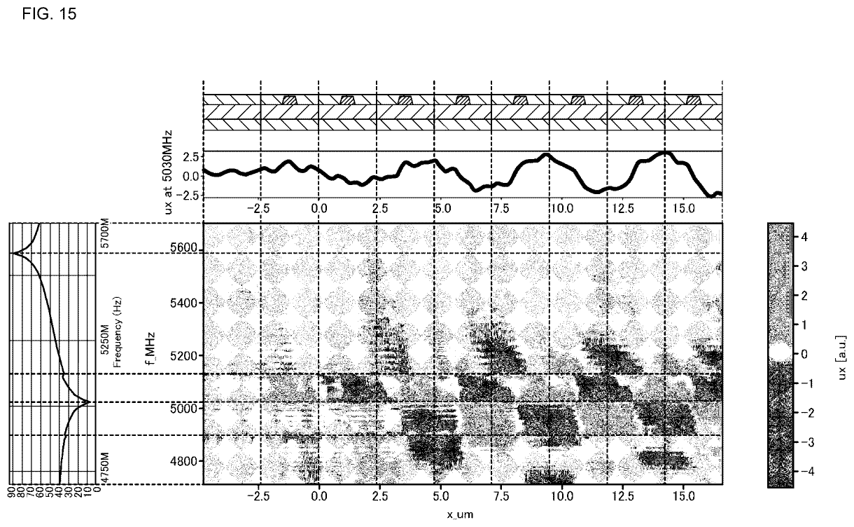

FIG. 14 is an explanatory diagram showing a distribution of vibration modes in the acoustic wave device according to the first example embodiment. FIG. 15 is an explanatory diagram showing a distribution of vibration modes in the acoustic wave device according to a comparative example. In the comparative example shown in FIG. 15, the acoustic wave device has the structure including the electrode fingers 31 and 32 all having equal or substantially equal electrode widths and equal or substantially equal inter-electrode pitches as compared to the acoustic wave device 10 according to the first example embodiment.

Each of FIGS. 14 and 15 shows a distribution of the magnitude of displacement of the piezoelectric layer 20 in the first example embodiment or the comparative example, with the horizontal axis representing the X direction (the arrangement direction of the electrode fingers 31 and 32) and the vertical axis representing the frequency. An upper diagram in each of FIGS. 14 and 15 shows a schematic sectional view of the acoustic wave device along the X direction, and a left diagram in each of FIGS. 14 and 15 shows impedance characteristics of the acoustic wave device.

As shown in FIG. 15, in the acoustic wave device according to the comparative example, an X-direction dependency in displacement (the X-direction positions of antinodes and nodes in the displacement) has a large frequency dependency. For example, the X-direction positions including the peaks of the displacement vary depending on the frequency, and excitation between the electrodes is not stable. In addition, focusing on a certain X position (near X=about 5.0 μm), phase inversions occur at a resonant frequency of about 5030 MHz and at frequencies of about 4900 MHz and about 5120 MHz at which the ripples occur. In this way, the acoustic wave device according to the comparative example may fail to obtain an ideal excitation mode.

In contrast, as shown in FIG. 14, in the acoustic wave device 10 according to the first example embodiment, an X-direction dependency in displacement (the X-direction positions of antinodes and nodes in the displacement) does not have a frequency dependency. In other words, the X-direction positions including peaks of the displacement are constant regardless of the frequency, indicating that stable excitation occurs between the electrodes. Moreover, the magnitude (amplitude) of the displacement is constant in each region between the electrodes, and no phase inversion occurs at the resonant frequency and at the frequency array at which the ripples occur. Therefore, it is observed that the structure in which the electrode width W1 and inter-electrode pitch P3 of the first electrode finger 31a located in the outermost portion in the arrangement direction are only made different from the electrode width and the inter-electrode pitch P1 of the central electrode fingers 31c and 32c is capable of obtaining a more appropriate excitation mode than in the comparative example.

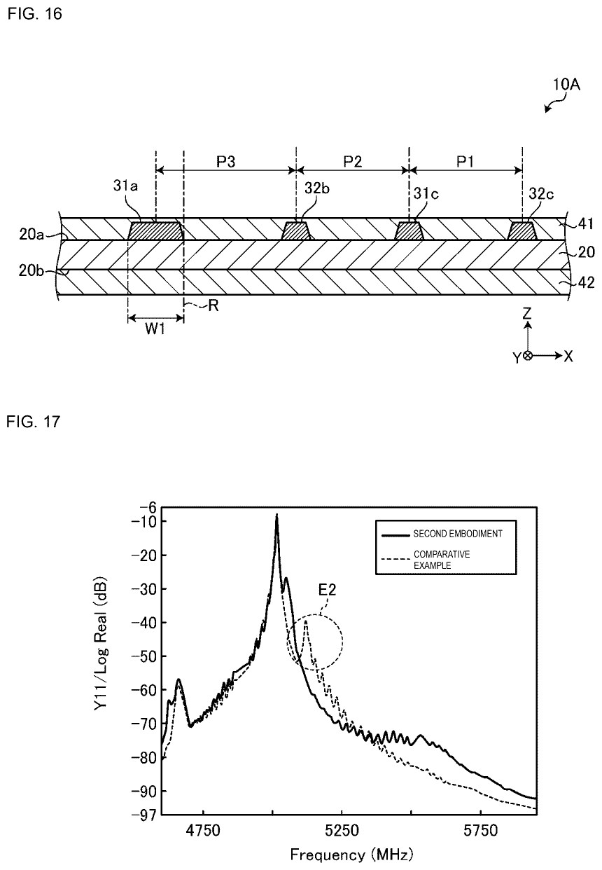

FIG. 16 is a sectional view illustrating an acoustic wave device according to a second example embodiment of the present invention. In the first example embodiment, the structure is described in which the electrode width of the first electrode finger 31a is smaller than the electrode width of the central electrode fingers 31c and 32c and the inter-electrode pitch P3 between the first electrode finger 31a and the second electrode finger 32b is smaller than the inter-electrode pitch P1 between the central electrode fingers 31c and 32c. However, the structure is not limited to this. As illustrated in FIG. 16, in an acoustic wave device 10A according to the second example embodiment, the electrode width of the first electrode finger 31a is larger than the electrode widths of the second electrode finger 32b and the central electrode fingers 31c and 32c. In addition, the inter-electrode pitch P3 is larger than the inter-electrode pitches P1 and P2. In the present example embodiment, the total number of electrode fingers 31 and 32 in the IDT electrode 30 is, for example, 51. The structures of the first protective film 41, the IDT electrode 30, and so on are the same or substantially the same as those in the first example embodiment. In the present example embodiment, the electrode width of the first electrode finger 31a is, for example, about 1.2 μm, and the electrode widths of the second electrode finger 32b and the central electrode fingers 31c and 32c are, for example, about 0.6 μm. Then, the inter-electrode pitch P3 is, for example, about 2.9 μm and the inter-electrode pitches P1 and P2 are, for example, about 2.38 μm.

Even in the case where the electrode width W1 and the inter-electrode pitch P3 of the first electrode finger 31a located in the outermost portion in the arrangement direction are larger than the electrode width and the inter-electrode pitch P1 of the central electrode fingers 31c and 32c as described above, in the region overlapping the first electrode finger 31a, an acoustic impedance different from those in the regions overlapping the other electrode fingers occurs. As a result, an acoustic reflection surface R is provided at an inner end portion of the first electrode finger 31a in the arrangement direction of the multiple electrode fingers 31 and 32.

Thus, acoustic waves excited in the piezoelectric layer 20 are reflected by the acoustic reflection surface R, and therefore the acoustic wave device 10A can reduce or prevent a leakage of acoustic waves in the arrangement direction of the multiple electrode fingers 31 and 32.

In the second example embodiment illustrated in FIG. 16, the structure is illustrated in which the electrode width of one first electrode finger 31a is larger than the electrode widths of the other electrode fingers 31 and 32, but the structure is not limited to this. Another structure may be possible in which the electrode width of multiple electrode fingers 31 and 32 located in the outermost portion in the arrangement direction of the multiple electrode fingers 31 and 32 is larger than the electrode width of the other electrode fingers 31 and 32 located in the central portion. Similarly, another structure may be possible in which the inter-electrode pitch between three or more electrode fingers 31 and 32 located in the outermost portion in the arrangement direction of the multiple electrode fingers 31 and 32 is larger than the inter-electrode pitch between the other electrode fingers 31 and 32 located in the central portion.

FIG. 17 is an explanatory diagram showing an example of admittance characteristics of the acoustic wave device according to the second example embodiment. As shown in FIG. 17, it is observed that, as in the acoustic wave device 10 according to the first example embodiment, the acoustic wave device 10A according to the second example embodiment, even having the structure in which the electrode width of the first electrode finger 31a is larger than the electrode width of the central electrode fingers 31c and 32c and the inter-electrode pitch P3 is larger than the inter-electrode pitches P1 and P2, reduces or prevents a ripple indicated by a dotted line E2 compared to a comparative example. Also in the second example embodiment, it is observed that a peak width related to the resonant frequency is narrowed, and therefore a propagation loss is reduced or prevented.

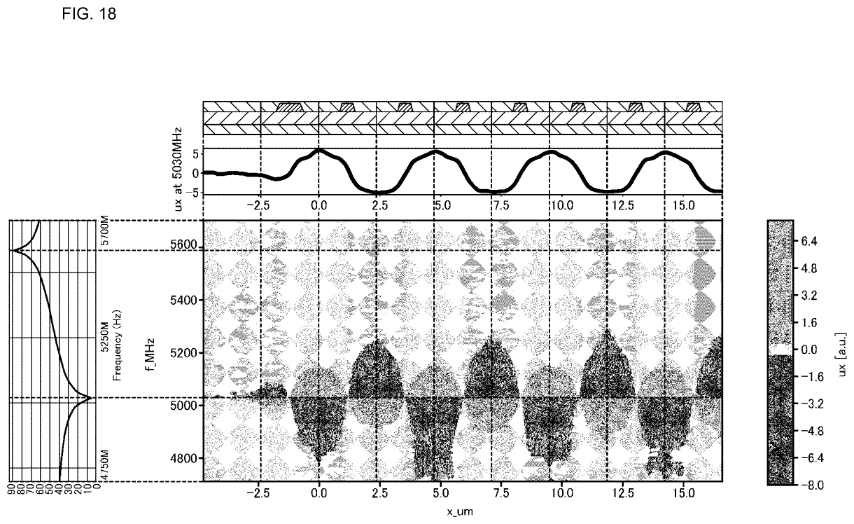

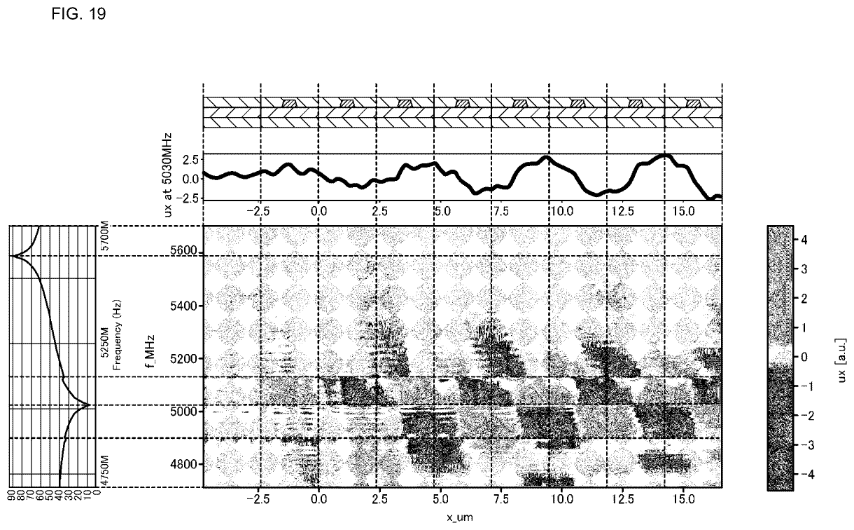

FIG. 18 is an explanatory diagram showing a distribution of vibration modes in the acoustic wave device according to the second example embodiment. FIG. 19 is an explanatory diagram showing a distribution of vibration modes in the acoustic wave device according to the comparative example. The comparative example shown in FIG. 19 includes a structure including the electrode fingers 31 and 32 all having equal or substantially equal electrode widths and equal or substantially equal inter-electrode pitches as compared to the acoustic wave device 10A according to the second example embodiment.

Each of FIGS. 18 and 19 shows a distribution of the magnitude of displacement of the piezoelectric layer 20 in the second example embodiment or the comparative example, with the horizontal axis representing the X direction (the arrangement direction of the electrode fingers 31 and 32) and the vertical axis representing the frequency. An upper diagram in each of FIGS. 18 and 19 shows a schematic sectional view of the acoustic wave device along the X direction, and a left diagram in each of FIGS. 18 and 19 shows impedance characteristics of the acoustic wave device.

As shown in FIG. 19, in the acoustic wave device according to the comparative example, an X-direction dependency in displacement (the X-direction positions of antinodes and nodes in the displacement) has a large frequency dependency. For example, the X-direction positions including the peaks of the displacement vary depending on the frequency, and excitation between the electrodes is not stable. In addition, focusing on a certain X position (near X=about 5.0 μm), phase inversions occur at a resonant frequency of about 5030 MHz and at the frequencies of about 4900 MHz and about 5120 MHz at which the ripples occur. In this way, the acoustic wave device according to the comparative example may fail to obtain an ideal excitation mode.

In contrast, as shown in FIG. 18, in the acoustic wave device 10A according to the second example embodiment, an X-direction dependency in displacement (the X-direction positions of antinodes and nodes in the displacement) does not have a frequency dependency. In other words, the X-direction positions including peaks of the displacement are constant regardless of the frequency, indicating that stable excitation occurs between the electrodes. Moreover, the magnitude (amplitude) of the displacement is constant in each region between the electrodes, and no phase inversion occurs at the resonant frequency and at the frequency array at which the ripples occur. Therefore, it is observed that the structure in which the electrode width W1 and inter-electrode pitch P3 of the first electrode finger 31a located in the outermost portion in the arrangement direction are larger than the electrode width and the inter-electrode pitch P1 of the central electrode fingers 31c and 32c is capable of obtaining a more appropriate excitation mode than in the comparative example.

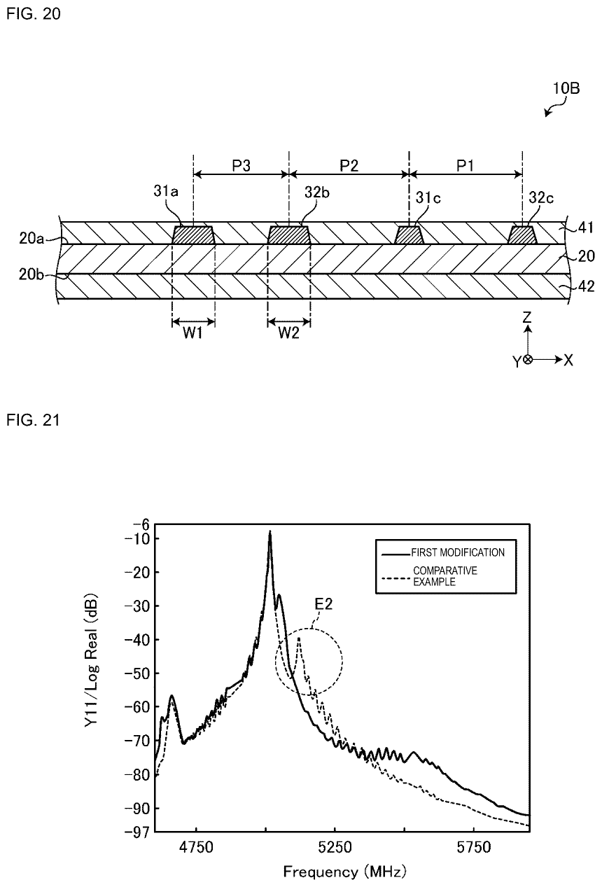

FIG. 20 is a sectional view illustrating an acoustic wave device according to a first modification of the second example embodiment. As illustrated in FIG. 20, in an acoustic wave device 10B according to the first modification, the electrode widths of the first electrode finger 31a and the second electrode finger 32b are larger than the electrode widths of the central electrode fingers 31c and 32c. In addition, the inter-electrode pitches P2 and P3 are different from the inter-electrode pitch P1. In the present modification, the total number of electrode fingers 31 and 32 in the IDT electrode 30 is, for example, 51. The structures of the first protective film 41, the IDT electrode 30, and so on are the same or substantially the same as those in the first example embodiment. In the present example embodiment, the electrode widths W1 and W2 of the first electrode finger 31a and the second electrode finger 32b are, for example, about 0.8 μm, and the electrode width of the central electrode fingers 31c and 32c is, for example, about 0.6 μm. The inter-electrode pitch P3 is, for example, about 1.91 μm, the inter-electrode pitch P2 is, for example, about 2.7 μm, and the inter-electrode pitch P1 is, for example, about 2.38 μm.

FIG. 21 is an explanatory diagram showing an example of admittance characteristics of the acoustic wave device according to the first modification of the second example embodiment. As shown in FIG. 21, it is observed that as in the acoustic wave device 10 according to the first example embodiment, the acoustic wave device 10B according to the first modification of the second example embodiment, even including the structure in which the electrode widths of the first electrode finger 31a and the second electrode finger 32b are larger than the electrode width of the central electrode fingers 31c and 32c and the inter-electrode pitches P2 and P3 are different from the inter-electrode pitch P1, reduces or prevents the ripple indicated by a dotted line E2 as compared to the comparative example. Also in the first modification of the second example embodiment, it is observed that a peak width related to the resonant frequency is narrowed, and therefore a propagation loss is reduced or prevented.

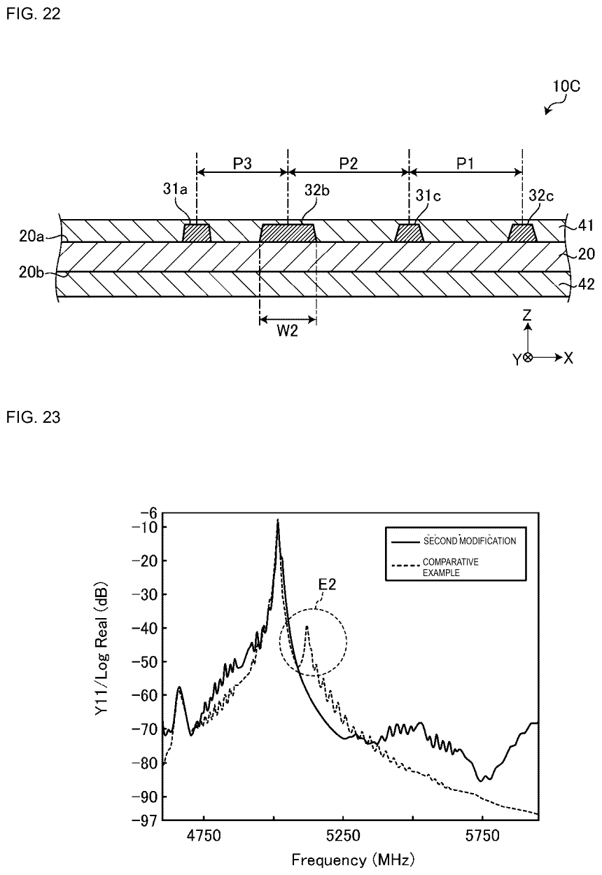

FIG. 22 is a sectional view illustrating an acoustic wave device according to a second modification of the second example embodiment. As illustrated in FIG. 22, in an acoustic wave device 10C according to the second modification, the electrode width of the second electrode finger 32b is larger than the electrode widths of the first electrode finger 31a and the central electrode fingers 31c and 32c. In addition, the inter-electrode pitches P2 and P3 are different from the inter-electrode pitch P1. In the present modification, the total number of electrode fingers 31 and 32 in the IDT electrode 30 is, for example, about 51. The structures of the first protective film 41, the IDT electrode 30, and so on are the same as those in the first example embodiment. In the present example embodiment, the electrode width W2 of the second electrode finger 32b is, for example, about 1.2 μm and the electrode widths of the first electrode finger 31a and the central electrode fingers 31c and 32c are, for example, about 0.6 μm. The inter-electrode pitch P3 is, for example, about 1.79 μm, the inter-electrode pitch P2 is, for example, about 2.9 μm, and the inter-electrode pitch P1 is, for example, about 2.38 μm.

FIG. 23 is an explanatory diagram showing an example of admittance characteristics of the acoustic wave device according to the second modification of the second example embodiment. As shown in FIG. 23, it is observed that as in the acoustic wave device 10 according to the first example embodiment, the acoustic wave device 10C according to the second modification of the second example embodiment, even including the structure in which the electrode widths of the first electrode finger 31a and the second electrode finger 32b are larger than the electrode width of the central electrode fingers 31c and 32c and the inter-electrode pitches P2 and P3 are different from the inter-electrode pitch P1, reduces or prevents the ripple indicated by a dotted line E2 as compared to the comparative example. Also in the second modification of the second example embodiment, it is observed that a peak width related to the resonant frequency is narrowed, and therefore a propagation loss is reduced or prevented.

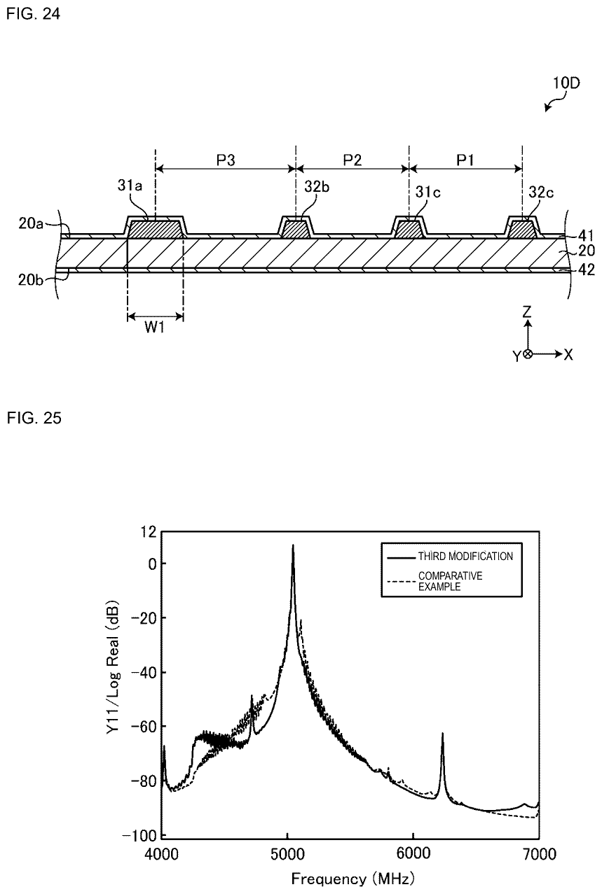

FIG. 24 is a sectional view illustrating an acoustic wave device according to a third modification of the second example embodiment. As illustrated in FIG. 24, in an acoustic wave device 10D according to the third modification, the film thickness of the first protective film 41 and the film thickness of the second protective film 42 are smaller than the film thickness of the IDT electrode 30. Also in the present modification, the electrode structure of the IDT electrode 30 is, for example, a multilayer film of Ti/AlCu/Ti/AlCu stacked from the piezoelectric layer 20 side, and their respective film thicknesses are about 12 nm/about 27 nm/about 18 nm/about 12 nm. In the present modification, the total number of electrode fingers 31 and 32 in the IDT electrode 30 is, for example, 101. The structures of the first protective film 41, and so on are the same or substantially the same as those in the first example embodiment. Specifically, the film thickness of the piezoelectric layer 20 is, for example, about 360 nm. The film thickness of the first protective film 41 is, for example, about 30 nm. The film thickness of the second protective film 42 is, for example, about 30 nm.

In the third modification, the first protective film 41 is provided along the surface and side surfaces of the electrode fingers 31 and 32 and the first main surface 20a of the piezoelectric layer 20. In the upper surface of the first protective film 41, projections and depressions reflecting the shapes of the electrode fingers 31 and 32 are provided. The second protective film 42 has a flat shape along the second main surface 20b of the piezoelectric layer 20.

The electrode width of the first electrode finger 31a is larger than the electrode widths of the second electrode finger 32b and the central electrode fingers 31c and 32c. In addition, the inter-electrode pitch P3 is larger than the inter-electrode pitches P1 and P2. In the present example embodiment, for example, the electrode width of the first electrode finger 31a is about 1.2 μm, and the electrode widths of the second electrode finger 32b and the central electrode fingers 31c and 32c are about 0.6 μm. The inter-electrode pitch P3 is, for example, about 2.9 μm and the inter-electrode pitches P1 and P2 are, for example, about 1.96 μm.

FIG. 25 is an explanatory diagram showing an example of admittance characteristics of the acoustic wave device according to the third modification of the second example embodiment. As shown in FIG. 25, it is observed that the acoustic wave device 10D according to the third modification reduces or prevents ripples as compared to a comparative example. Thus, even though the first protective film 41 and the second protective film 42 are provided on both of the first main surface 20a side and the second main surface 20b side of the piezoelectric layer 20 and the first protective film 41 and the second protective film 42 are thin, ripples are reduced or prevented and a propagation loss is reduced or prevented.

In the acoustic wave device 10D according to the third modification, the structure is described in which the film thickness of the first protective film 41 and the film thickness of the second protective film 42 are smaller than the film thickness of the IDT electrode 30, but the structure is not limited to this. A structure may be possible in which any one of the film thickness of the first protective film 41 and the film thickness of the second protective film 42 is smaller than the film thickness of the IDT electrode 30.

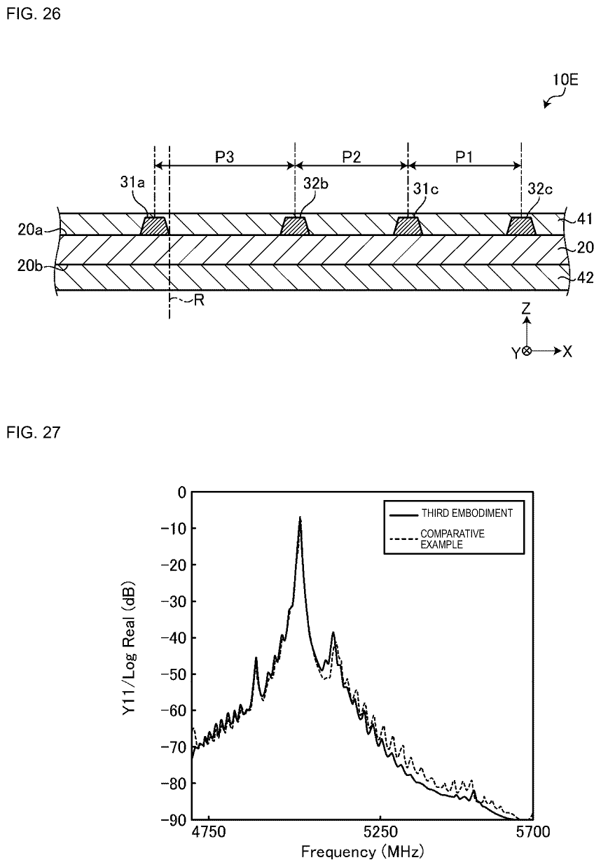

FIG. 26 is a sectional view illustrating an acoustic wave device according to a third example embodiment of the present invention. In the first example embodiment, the structure is described in which the electrode width of the first electrode finger 31a is smaller than the electrode width of the central electrode fingers 31c and 32c and the inter-electrode pitch P3 between the first electrode finger 31a and the second electrode finger 32b is smaller than the inter-electrode pitch P1 between the central electrode fingers 31c and 32c, but the structure is not limited to this. As illustrated in FIG. 26, in an acoustic wave device 10E according to the third example embodiment, the electrode widths of the first electrode finger 31a, the second electrode finger 32b, and the central electrode fingers 31c and 32c are equal or substantially equal to each other. In addition, the inter-electrode pitch P3 is larger than the inter-electrode pitches P1 and P2. The structures of the first protective film 41, the IDT electrode 30, and so on are the same or substantially the same as those in the first example embodiment. In the present example embodiment, the electrode widths of the first electrode finger 31a, the second electrode finger 32b, and the central electrode fingers 31c and 32c are, for example, about 0.6 μm. The inter-electrode pitch P3 is, for example, about 2.68 μm and the inter-electrode pitches P1 and P2 are, for example, about 2.38 μm.

Even in the case where the electrode width W1 of the first electrode finger 31a located in the outermost portion in the arrangement direction is equal or substantially equal to the electrode width of the central electrode fingers 31c and 32c, the inter-electrode pitch P3 is made different from the inter-electrode pitch P1 of the central electrode fingers 31c and 32c as described above. In this case, in a region overlapping the first electrode finger 31a, an acoustic impedance different from those in regions overlapping the other electrode fingers occurs. As a result, an acoustic reflection surface R is provided at an inner end portion of the first electrode finger 31a in the arrangement direction of the multiple electrode fingers 31 and 32.

Thus, acoustic waves excited in the piezoelectric layer 20 are reflected by the acoustic reflection surface R, and therefore the acoustic wave device 10E can reduce or prevent a leakage of acoustic waves in the arrangement direction of the multiple electrode fingers 31 and 32.

FIG. 27 is an explanatory diagram showing an example of admittance characteristics of the acoustic wave device according to the third example embodiment. As shown in FIG. 27, it is observed that as in the acoustic wave device 10 according to the first example embodiment, the acoustic wave device 10E according to the third example embodiment, even including the structure in which the electrode width of the first electrode finger 31a is equal or substantially equal to the electrode width of the central electrode fingers 31c and 32c and the inter-electrode pitch P3 is larger than the inter-electrode pitches P1 and P2, reduces or prevents ripples as compared to the comparative example. Also in the third example embodiment, it is observed that a peak width related to the resonant frequency is narrowed, and therefore a propagation loss is reduced or prevented.

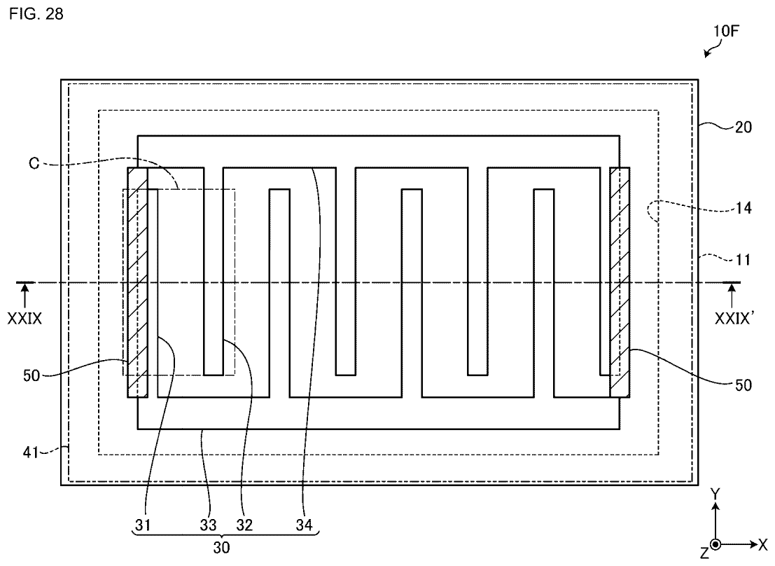

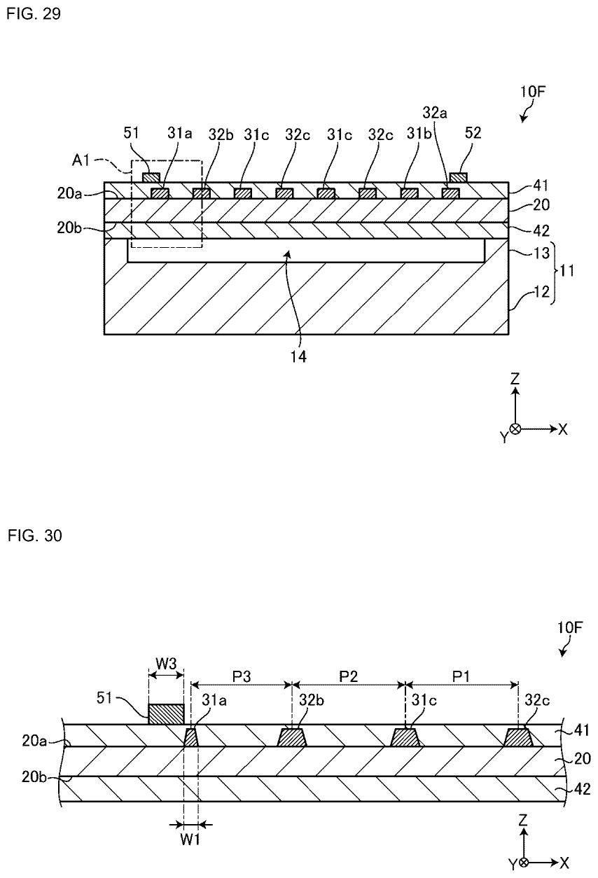

FIG. 28 is a plan view illustrating an acoustic wave device in a fourth example embodiment of the present invention. FIG. 29 is a sectional view taken along XXIX-XXIX′ in FIG. 28. In FIG. 28, a load film 50 is illustrated with hatching to make the drawing easier to see. In FIG. 28, the first protective film 41 is illustrated by a dash-double-dot line.

As illustrated in FIGS. 28 and 29, an acoustic wave device 10F according to the fourth example embodiment further includes the load film 50. As illustrated in FIG. 29, in the acoustic wave device 10F, the load film 50 is stacked on the first protective film 41.

A portion of the load film 50 overlapping the first electrode finger 31a is referred to as a first extension portion 51 and a portion of the load film 50 overlapping the third electrode finger 32a is referred to as a second extension portion 52. The first extension portion 51 and the second extension portion 52 are spaced apart from each other in the arrangement direction of the multiple electrode fingers 31 and 32, and the multiple electrode fingers 31 and 32 are arranged between the first extension portion 51 and the second extension portion 52. The first extension portion 51 extends in the extension direction of the first electrode finger 31a while overlapping a portion of the first electrode finger 31a. The second extension portion 52 extends in the extension direction of the third electrode finger 32a while overlapping a portion of the third electrode finger 32a.

FIG. 30 is an enlarged sectional view illustrating a region Al illustrated in FIG. 29. In FIG. 30, the load film 50 (the first extension portion 51) overlapping the first electrode finger 31a will be described, but the second extension portion 52 overlapping the third electrode finger 32a (see FIGS. 28 and 29) also has an arrangement relationship linearly symmetrical with that of the first extension portion 51. Description of the first extension portion 51 can also apply to the second extension portion 52. In the following description, in a case where there is no need to distinguish between the first extension portion 51 and the second extension portion 52, they will be simply referred to as the load film 50.

In the present example embodiment, the load film 50 is made of the same material as the first protective film 41. In the present example embodiment, the load film 50 and the first protective film 41 are made of, for example, silicon oxide (SiO₂). Even in the case where the load film 50 and the first protective film 41 are made of the same material, the density of the load film 50 may be different from the density of the first protective film 41. For example, in a case where the load film 50 is formed by vapor deposition, the actual density of the load film 50 is lower than the density of the first protective film 41.

As illustrated in FIG. 30, in an acoustic wave device 10F according to the fourth example embodiment, the electrode width of the first electrode finger 31a located in the outermost portion in the arrangement direction of the multiple electrode fingers 31 and 32 is smaller than the electrode width of the electrode fingers 31 and 32 located in the central portion in the arrangement direction. In addition, the outermost inter-electrode pitch P3 in the arrangement direction is smaller than the inter-electrode pitch P1 in the central portion inside the inter-electrode pitch P2. The structures of the first protective film 41, the IDT electrode 30, and so on are the same or substantially the same as those in the first example embodiment. In the present example embodiment, the electrode width W1 of the first electrode finger 31a is, for example, about 0.3 μm, and the electrode widths of the second electrode finger 32b and the central electrode fingers 31c and 32c are, for example, about 0.6 μm. The inter-electrode pitch P3 is, for example, about 2.23 μm and the inter-electrode pitches P1 and P2 are, for example, about 2.38 μm.

In an acoustic wave device 10F according to the fourth example embodiment, the load film 50 is provided in a region not overlapping the first electrode finger 31a. Specifically, the load film 50 is provided in an outer region in the arrangement direction, which is outside the first electrode finger 31a located in the outermost portion in the arrangement direction of the multiple electrode fingers 31 and 32 among the multiple electrode fingers 31 and 32, and which does not overlap the IDT electrode 30. The width W3 of the load film 50 is, for example, about 0.6 μm. The film thickness of the load film 50 is, for example, about 90 nm.

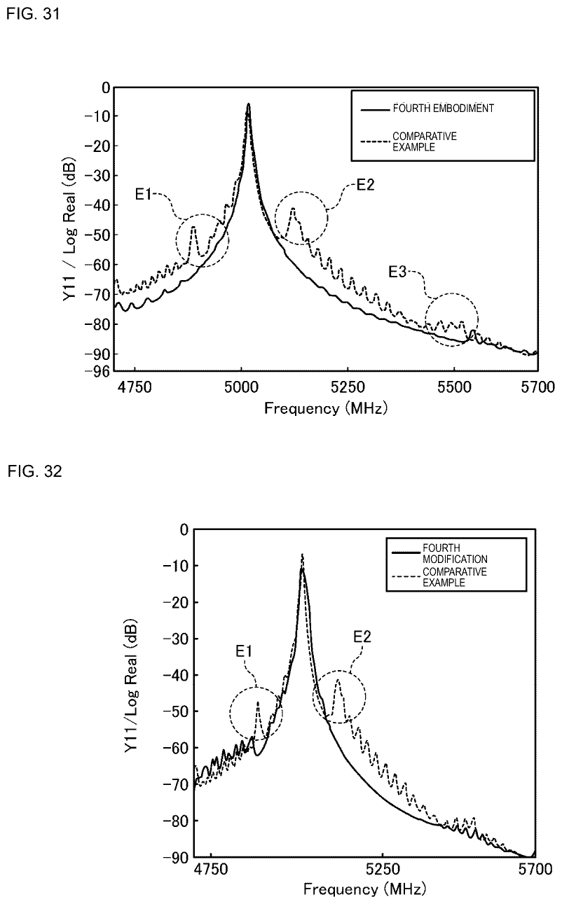

FIG. 31 is an explanatory diagram showing an example of admittance characteristics of the acoustic wave device according to the fourth example embodiment. As shown in FIG. 31, the acoustic wave device 10F according to the fourth example embodiment reduces or prevents the ripples indicated by dotted lines E1, E2, and E3 as compared to the comparative example. Even in the case where the structure includes the load film 50 as described above, ripples are reduced or prevented and a propagation loss is reduced or prevented. In addition, the acoustic wave device 10F according to the fourth example embodiment effectively reduces or prevents a propagation loss over a wide frequency range from about 4700 MHz to about 5500 MHz, as compared to the above-described example embodiments and modifications.

The shape, width, film thickness, and so on of the load film 50 are merely examples, and may be changed as appropriate. For example, the side surfaces of the load film 50 may have a tapered shape. The first extension portion 51 and the second extension portion 52 of the load film 50 illustrated in FIG. 28 may have the same or substantially the same width and the same or substantially the same film thickness. Alternatively, the first extension portion 51 and the second extension portion 52 of the load film 50 may have different widths and different film thicknesses due to, for example, variations in a manufacture process.

The material for the load film 50 described in the fourth example embodiment is merely an example, and a material for the load film 50 is not limited to this. As a material for the load film 50, for example, at least one of carbon-doped silicon oxide (SiOC), silicon oxide (SiO₂), silicon nitride (SiN), tantalum pentoxide (Ta₂O₅), aluminum nitride (AlN), aluminum oxide (Al₂O₃), hafnium oxide (HfO₂), niobium pentoxide (Nb₂O₅), or tungsten oxide (WO) may be used. The load film 50 may include a combination of two or more of the above materials.

In the fourth example embodiment illustrated in FIG. 30, the structure is illustrated in which the load film 50 is provided in the region not overlapping the first electrode finger 31a, but the structure is not limited to this. In the fourth example embodiment and a fourth modification described below, the load film 50 may be provided in a region overlapping the first electrode finger 31a. The load film 50 is provided on the first protective film 41, but the structure is not limited to this. The fourth example embodiment may be combined with any of the foregoing example embodiments and modifications.

FIG. 32 is an explanatory diagram showing an example of admittance characteristics of an acoustic wave device according to a fourth modification of the fourth example embodiment. The acoustic wave device according to the fourth modification is different from the acoustic wave device 10F according to the fourth example embodiment in dimensions of the load film 50. More specifically, for example, the load film 50 in the fourth modification has a film thickness of about 60 nm and a width W3 of about 0.8 μm. The structures of the load film 50, the first protective film 41, the IDT electrode 30, and so on are the same or substantially the same as those in the fourth example embodiment. As shown in FIG. 32, the acoustic wave device according to the fourth modification of the fourth example embodiment reduces or prevents the ripples indicated by dotted lines E1 and E2 as compared to the comparative example. Even in the case where the dimensions of the load film 50 are changed as described above, ripples are reduced or prevented and a propagation loss is reduced or prevented. In addition, the acoustic wave device according to the fourth modification of the fourth example embodiment effectively reduces or prevents a propagation loss over a wide frequency range from about 4700 MHz to about 5500 MHz, as compared to the above-described example embodiments and modifications.

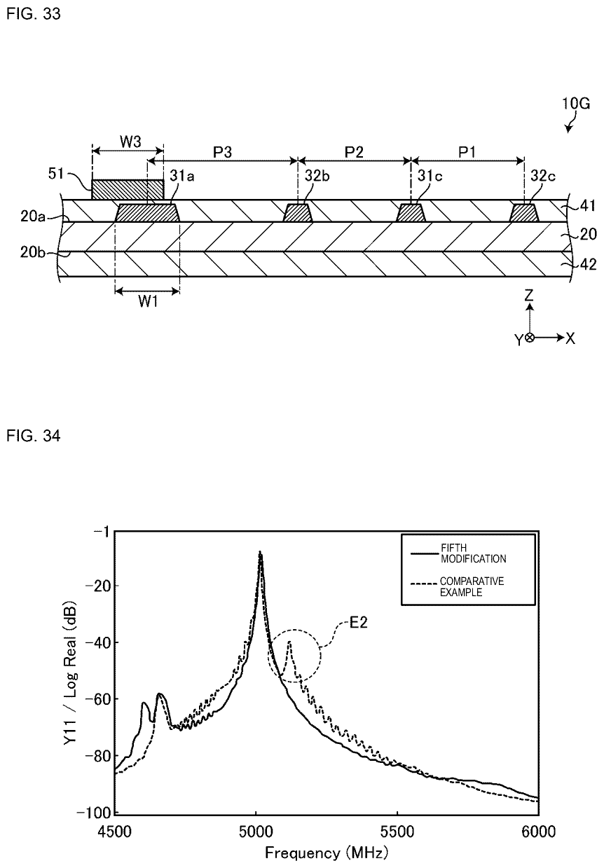

FIG. 33 is a sectional view illustrating an acoustic wave device according to a fifth modification of the fourth example embodiment of the present invention. As illustrated in FIG. 33, in an acoustic wave device 10G according to the fifth modification of the fourth example embodiment, the electrode width W1 of the first electrode finger 31a located in the outermost portion in the arrangement direction of the multiple electrode fingers 31 and 32 is larger than the electrode widths of the electrode fingers 31 and 32 located in the central portion in the arrangement direction. Moreover, the outermost inter-electrode pitch P3 in the arrangement direction is larger than the inter-electrode pitch P1 in the central portion inside the inter-electrode pitch P2. The structures of the load film 50, the first protective film 41, the IDT electrode 30, and so on are the same or substantially the same as those in the fourth example embodiment. In the present example, for example, the electrode width of the first electrode finger 31a located in the outermost portion in the arrangement direction is about 1.0 μm, and the electrode width of the other electrode fingers 31 and 32 located in the central portion is about 0.6 μm. Then, the outermost inter-electrode pitch P3 in the arrangement direction is, for example, about 2.58 μm and the inter-electrode pitch P1 and p2 in the central portion inside the inter-electrode pitch P3 is, for example, about 2.38 μm.

In the fifth modification of the fourth example embodiment, the load film 50 is provided in a region overlapping the first electrode finger 31a located in the outermost portion in the arrangement direction of the multiple electrode fingers 31 and 32 among the multiple electrode fingers 31 and 32. The width W3 of the load film 50 is, for example, about 0.8 μm. The film thickness of the load film 50 is, for example, about 15 nm. One of side surfaces of the load film 50 is arranged at a position shifted from the widthwise center of the first electrode finger 31a to the second electrode finger 32b side. The width of a region of the load film 50 overlapping the first electrode finger 31a is, for example, about 0.7 μm. The width of a not-overlapping region of the load film 50 is, for example, about 0.1 μm.

FIG. 34 is an explanatory diagram showing an example of admittance characteristics of the acoustic wave device according to the fifth modification of the fourth example embodiment. As shown in FIG. 34, the acoustic wave device 10G according to the fifth modification of the fourth example embodiment reduces or prevents the ripple indicated by a dotted line E2 as compared to the comparative example. Thus, even the structure in which the electrode width of the first electrode finger 31a is larger than the electrode widths of the other electrode fingers 31 and 32 and the inter-electrode pitch P3 is larger than the inter-electrode pitch P1 and P2 reduces or prevents a ripple and reduces or prevents a propagation loss.

In the fifth modification of the fourth example embodiment illustrated in FIG. 33, the structure is illustrated in which the load film 50 is provided in the region overlapping the first electrode finger 31a, but the structure is not limited to this. In addition, the load film 50 is provided on the first protective film 41, but the structure is not limited to this. The fifth modification of the fourth example embodiment may be combined with any of the foregoing example embodiments and modifications.

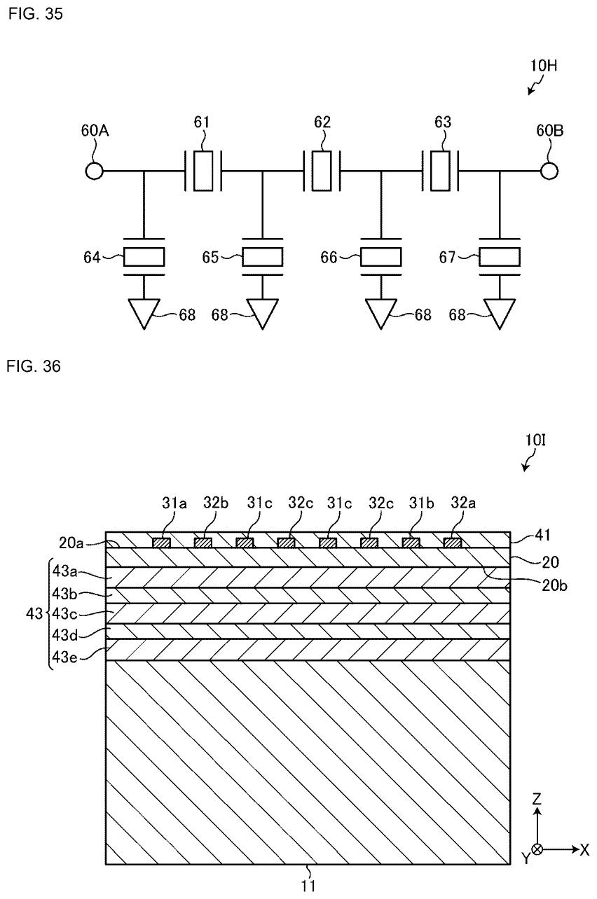

FIG. 35 is a circuit diagram illustrating an acoustic wave filter apparatus according to a fifth example embodiment of the present invention.

As illustrated in FIG. 35, an acoustic wave filter apparatus 10H according to the fifth example embodiment includes multiple series arm resonators 61, 62, and 63, and multiple parallel arm resonators 64, 65, 66, and 67. The multiple series arm resonators 61, 62, and 63 are coupled in series to a signal path between an input terminal 60A and an output terminal 60B. The multiple parallel arm resonators 64, 65, 66, and 67 are coupled in parallel between a ground 68 and the signal path between the input terminal 60A and the output terminal 60B. The acoustic wave filter apparatus 10H according to the fifth example embodiment is a so-called ladder filter.

One of terminals of each of the multiple series arm resonators 61, 62, and 63 coupled in series is electrically coupled to the input terminal 60A, and the other terminal is electrically coupled to the output terminal 60B. One of terminals of the parallel arm resonator 64 is electrically coupled to the input terminal 60A and the other terminal is electrically coupled to the ground 68. One of terminals of the parallel arm resonator 65 is electrically coupled to a signal path coupling the series arm resonators 61 and 62 and the other terminal is electrically coupled to the ground 68. One of terminals of the parallel arm resonator 66 is electrically coupled to a signal path coupling the series arm resonators 62 and 63 and the other terminal is electrically coupled to the ground 68. One of terminals of the parallel arm resonator 67 is electrically coupled to the output terminal 60B and the other terminal is electrically coupled to the ground 68.

In the present example embodiment, the multiple series arm resonators 61, 62, and 63 and the multiple parallel arm resonators 64, 65, 66, and 67 include respectively different structures of electrode fingers. The present example embodiment can obtain a better output waveform as a filter due to the use of the respectively different structures of the electrode fingers 31 and 32 in the multiple series arm resonators 61, 62, and 63 and the multiple parallel arm resonators 64, 65, 66, and 67.

The fifth example embodiment may be combined with any of the foregoing example embodiments and modifications.

FIG. 36 is a sectional view illustrating an acoustic wave device according to a sixth example embodiment of the present invention. In the foregoing acoustic wave device 10 in the first example embodiment, the membrane structure is described in which the supporting substrate 11 includes the cavity portion 14, and the cavity portion 14 (hollow portion) is provided on the second main surface 20b side of the piezoelectric layer 20, but the structure is not limited to this.

As illustrated in FIG. 36, in an acoustic wave device 10I according to the sixth example embodiment, an acoustic multilayer film 43 is stacked on the second main surface 20b of the piezoelectric layer 20. The acoustic multilayer film 43 has a multilayer structure including low acoustic impedance layers 43a, 43c, and 43e with a relatively low acoustic impedance and high acoustic impedance layers 43b and 43d with a relatively high acoustic impedance. Each of the low acoustic impedance layers 43a, 43c, and 43e is, for example, a SiO₂ layer, and each of the high acoustic impedance layers 43b and 43d is, for example, a metal layer of W, Pt, or the like or a dielectric layer of aluminum nitride, silicon nitride, or the like. In the case where the acoustic multilayer film 43 is used, the acoustic wave device 10I can confine the bulk waves in the thickness-shear primary mode inside the piezoelectric layer 20 without using the cavity portion 14.

In the case where d/p is set to, for example, about 0.5 or less as described above, the acoustic wave device 10I can also obtain the resonance characteristics based on the bulk waves of the thickness-shear primary mode. In the acoustic multilayer film 43, the number of low acoustic impedance layers 43a, 43c, and 43e and the high acoustic impedance layers 43b and 43d in the multilayer structure is not particularly limited. It is only necessary that at least one high acoustic impedance layer 43b or 43d be arranged farther from the piezoelectric layer 20 than a low acoustic impedance layer 43a, 43c, or 43e.

The low acoustic impedance layers 43a, 43c, and 43e and the high acoustic impedance layers 43b and 43d described above may be made of any appropriate materials as long as they can satisfy the above acoustic impedance relationship. For example, a material for the low acoustic impedance layers 43a, 43c, and 43e is silicon oxide, silicon oxynitride, or the like. A material for the high acoustic impedance layers 43b and 43d is alumina, silicon nitride, metal, or the like.

The sixth example embodiment may be combined with any of the foregoing example embodiments and modifications.

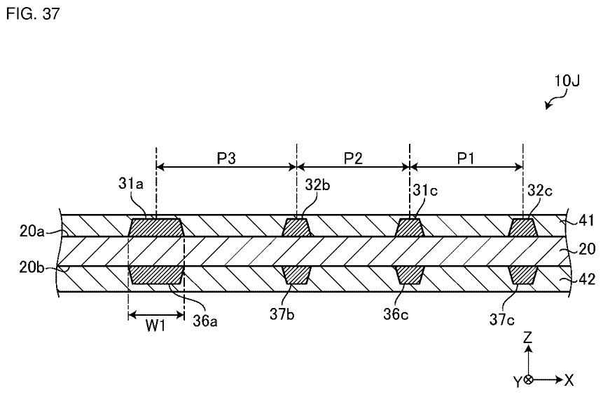

FIG. 37 is a sectional view illustrating an acoustic wave device according to a seventh example embodiment of the present invention. In the foregoing acoustic wave device 10 in the first example embodiment, the structure is described in which the IDT electrode 30 is provided on the first main surface 20a of the piezoelectric layer 20, but the structure is not limited to this. As illustrated in FIG. 37, an acoustic wave device 10J according to the seventh example embodiment includes a first IDT electrode provided on the first main surface 20a of the piezoelectric layer 20 and a second IDT electrode provided on the second main surface 20b of the piezoelectric layer 20. The first IDT electrode and the second IDT electrode have the same or substantially the same structure as in the IDT electrode 30 (see FIGS. 1 and 2).

Electrode fingers 36 and 37 of the second IDT electrode are provided in regions overlapping electrode fingers 31 and 32 of the first IDT electrode. The electrode fingers 36 and 37 of the second IDT electrode are provided with the same or substantially the same widths and the same or substantially the same inter-electrode pitches as the electrode fingers 31 and 32 of the first IDT electrode. In FIG. 37, a first electrode finger 36a and a central electrode finger 36c are examples of the electrode fingers 36 and a second electrode finger 37b and a central electrode finger 37c are examples of the electrode fingers 37.

In the seventh example embodiment, since the first IDT electrode and the second IDT electrode are provided on the first main surface 20a and the second main surface 20b of the piezoelectric layer 20, respectively, a temperature coefficient of frequency (TCF) can be improved.

FIG. 37 illustrates the example in which the electrode fingers 31 and 32 in the first example embodiment are provided, but the structure is not limited to this. The seventh example embodiment may be combined with any of the foregoing example embodiments and modifications.

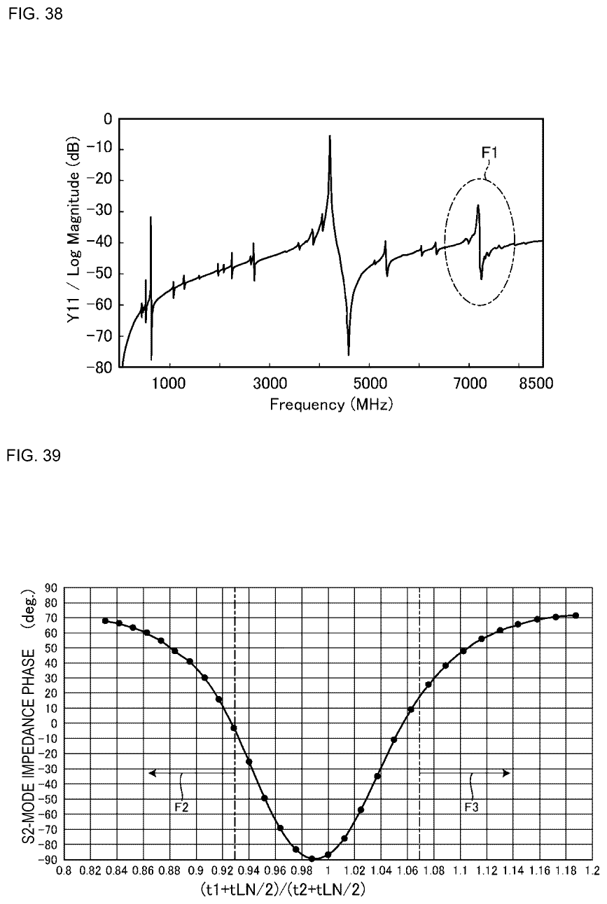

FIG. 38 is an explanatory diagram showing an example of admittance characteristics of the acoustic wave device according to an eighth example embodiment. FIG. 39 is an explanatory diagram showing an example of an impedance phase in a high-order mode. An acoustic wave device according to the eighth example embodiment illustrated in FIG. 38 is for explaining a structure in which the first protective film 41 and the second protective film 42 in the acoustic wave device 10 according to the first example embodiment described above have different film thicknesses.

FIG. 38 shows frequency characteristics of the absolute value of admittance of the acoustic wave device according to the eighth example embodiment. As shown in FIG. 38, in the acoustic wave device according to the eighth example embodiment, resonance in a high-order mode occurs in a frequency domain indicated by a dash-dot line F1, which is different from a resonant frequency (hereinafter referred to as the S2 mode).

In a graph shown in FIG. 39, the horizontal axis represents a ratio ((t1+tLN/2)/(t2+tLN/2)) of the sum (t1+tLN/2) of the thickness t1 of the first protective film 41 and about ½ of the thickness tLN of the piezoelectric layer 20 to the sum (t2+tLN/2) of the thickness t2 of the second protective film 42 and about ½ of the thickness tLN of the piezoelectric layer 20. In the graph shown in FIG. 39, the vertical axis corresponds to the magnitude of the S2 mode.

In FIG. 39, ranges marked by arrows F2 and F3 indicate the ratio (t1+tLN/2)/(t2+tLN/2) in the structure of an acoustic resonator apparatus described in Japanese Unexamined Patent Application Publication No. 2022-524136. In the acoustic resonator apparatus described in Japanese Unexamined Patent Application Publication No. 2022-524136, the ratio (t1+tLN/2)/(t2+tLN/2) is, for example, about 0.93 or less and about 1.07 or more and the magnitude of the S2 mode is high.

In contrast, in the eighth example embodiment, the ratio (t1+tLN/2)/(t2+tLN/2) is, for example, within a range of about 0.94 or more to about 1.06 or less and the magnitude of the S2 mode is lower than in the acoustic resonator apparatus described in Japanese Unexamined Patent Application Publication No. 2022-524136. In other words, in the eighth example embodiment, a value A/B is, for example, preferably about 1-0.06 or more and about 1+0.06 or less, where A denotes a total distance from the center of the film thickness of the piezoelectric layer 20 to the top surface of the first protective film 41 and B denotes a total distance from the center of the film thickness of the piezoelectric layer 20 to the bottom surface of the second protective film 42.

In the eighth example embodiment, the case where the first protective film 41 and the second protective film 42 have the different film thicknesses in the acoustic wave device 10 according to the first example embodiment is described, but the case is not limited to this. The relationship among the film thickness t1 of the first protective film 41, the film thickness tLN of the piezoelectric layer 20, and the film thickness t2 of the second protective film 42 in the eighth example embodiment may be combined with any of the foregoing example embodiments and modifications.

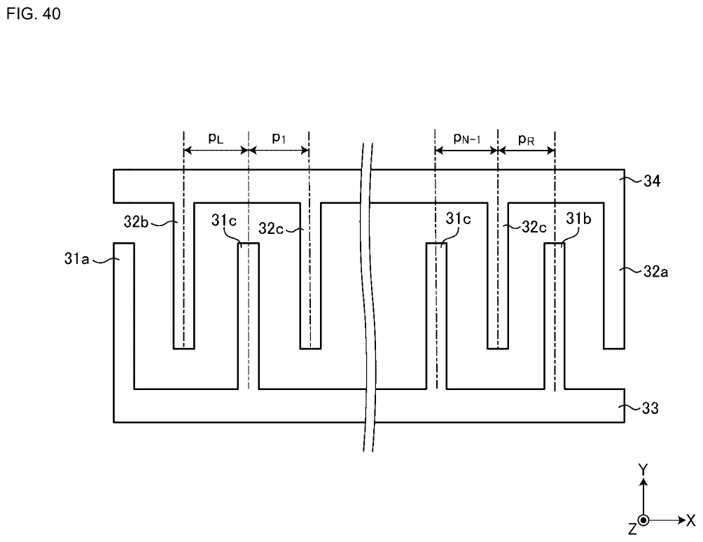

FIG. 40 is a plan view illustrating an IDT electrode of an acoustic wave device according to a ninth example embodiment of the present invention. Here, the number of central electrode fingers 31c and 32c is denoted as N.

The ninth example embodiment will be described, as shown in FIG. 40, where pₙ denotes an inter-electrode pitch between an n-th central electrode finger (n is an integer of 1 or more to N−1 or less) and an (n+1)-th central electrode finger counted in the X direction from the electrode finger adjacent to the second electrode finger 1 electrode fingers, pr denotes an inter-electrode pitch between the first electrode finger counted in the X direction and an electrode finger externally adjacent to the first electrode finger in the arrangement direction, i.e., the second electrode finger 32b, and PR denotes an inter-electrode pitch between the N-th electrode finger counted in the X direction and an electrode finger externally adjacent to the N-th electrode finger in the X direction, i.e., the fourth electrode finger 31b. In this case, inter-electrode pitch change rates prₙ, pr_{L}, and pr_{R} are defined as values expressed by Formulas (4) to (6) below, respectively. In addition, an arithmetic mean of the inter-electrode pitch change rates prₙ expressed by Formula (7) below is referred to as an average inter-electrode pitch change rate pr_{A}. In the present disclosure, an average inter-electrode pitch change rate of the central electrode fingers 31c and 32c refers to the average inter-electrode pitch change rate pr_{A}, and the inter-electrode pitch change rate of an electrode finger (the fourth electrode finger 31b or the second electrode finger 32b) externally adjacent to the central electrode finger 31c or 32c in the arrangement direction (X direction) refers to at least one of the inter-electrode pitch change rates pr_{L} and pr_{R}:

$${pr}_{n} = \vert ( {p}_{n + 1} - {p}_{n} ) / {p}_{n} \vert \qquad Formula ( 4 )$$

$${pr}_{L} = ( {p}_{1} - {p}_{L} ) / {p}_{L} \qquad Formula ( 5 )$$

$${pr}_{R} = ( {p}_{N - 1} - {p}_{R} ) / {p}_{R} \qquad Formula ( 6 )$$

$$\begin{matrix}Formula 1 & \\ {pr}_{A} = \frac{1}{N - 1} {\sum }_{k = 1}^{N - 1} {pr}_{k} & Formula ( 7 )\end{matrix}$$

In the ninth example embodiment, the inter-electrode pitch change rates pr_{L} and pr_{R} are made different from the average inter-electrode pitch change rate pr_{A}. Here, the inter-electrode pitch between the first electrode finger 31a and the second electrode finger 32b is equal or substantially equal to the inter-electrode pitch p_{L} and the inter-electrode pitch between the fourth electrode finger 31b and the third electrode finger 32a is equal or substantially equal to the inter-electrode pitch p_{R}.

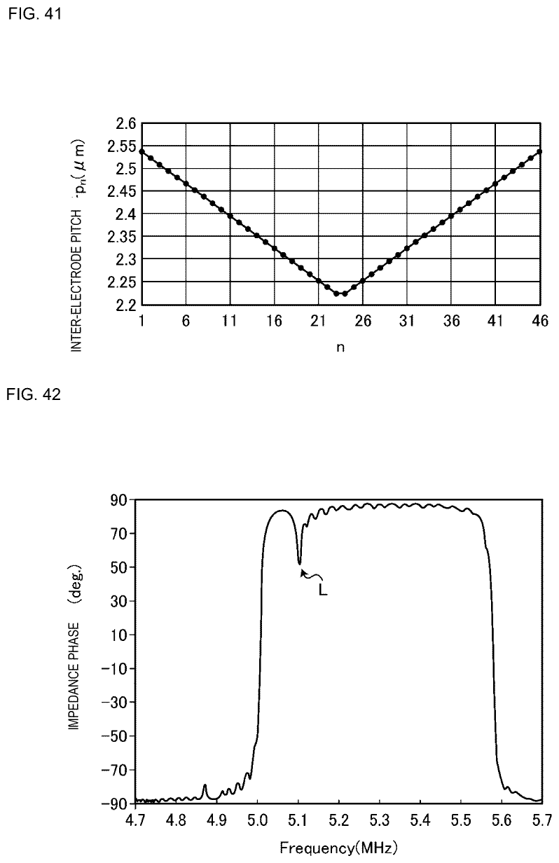

FIG. 41 is an explanatory diagram showing the inter-electrode pitches pₙ in the acoustic wave device according to the ninth example embodiment. In the ninth example embodiment, the total number of the electrode fingers 31 and the electrode fingers 32 in the IDT electrode 30 is, for example, 51. In other words, in the ninth example embodiment, N is equal to, for example, 47. As shown in FIG. 41, in the acoustic wave device according to the ninth example embodiment, the inter-electrode pitches pₙ decrease as n increments from n=1 to n (n=23) closest to N/2, are minimized at n (n=23, 24) closest to (N+1)/2, and then increase as n increments from n (n=24) closest to (N+1)/2 to n=N−1 (n=46). In sum, the inter-electrode pitches pₙ between the central electrode fingers 31c and 32c according to the ninth example embodiment decrease toward the center among the central electrode fingers 31c and 32c. Here, the average inter-electrode pitch change rate pr_{A} according to the ninth example embodiment is, for example, about 0.006. In addition, the average inter-electrode pitch between the central electrode fingers 31c and 32c according to the ninth example embodiment is, for example, about 2.38 μm.

In the acoustic wave device according to the ninth example embodiment, the electrode widths of the first electrode finger 31a, the second electrode finger 32b, the third electrode finger 32a, the fourth electrode finger 31b, and the central electrode fingers 31c and 32c are equal or substantially equal to each other. The electrode widths of the first electrode finger 31a, the second electrode finger 32b, the third electrode finger 32a, the fourth electrode finger 31b, and the central electrode fingers 31c and 32c are, for example, about 0.6 μm.

In addition, in the ninth example embodiment, the electrode structure of the IDT electrode 30 is, for example, a multilayer film of Ti/AlCu/Ti/AlCu stacked from the piezoelectric layer 20 side, and their respective film thicknesses are about 12 nm/about 70 nm/about 18 nm/about 12 nm. The structures of the first protective film 41 and so on are the same or substantially the same as those in the first example embodiment. Specifically, the film thickness of the piezoelectric layer 20 is, for example, about 181 nm. The film thickness of the first protective film 41 is, for example, about 142 nm. The film thickness of the second protective film 42 is, for example, about 142 nm.

FIG. 42 is an explanatory diagram showing an impedance phase of an acoustic wave device according to a comparative example 1. The comparative example 1 shown in FIG. 42 has a structure including the electrode fingers 31 and 32 all having equal or substantially equal electrode widths and equal or substantially equal inter-electrode pitches as compared to the acoustic wave device according to the ninth example embodiment. As shown in FIG. 42, the phase is dropped and a leaky wave L is generated at about 5102 MHz in the acoustic wave device according to the comparative example 1.

A comparative example 2 has the same or substantially the same structure as in the acoustic wave device according to the ninth example embodiment except that the inter-electrode pitch change rates pr_{L} and pr_{R} are set to about 0, i.e., the inter-electrode pitch p_{L} is equalized to p₁ and the inter-electrode pitch PR is equalized to p_{N-1}.

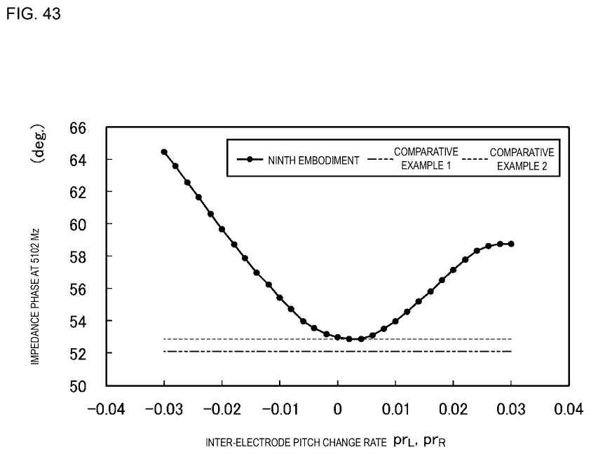

FIG. 43 is an explanatory diagram showing impedance phases at about 5102 MHz in the acoustic wave devices according to the ninth example embodiment and the comparative examples 1 and 2. As shown in FIG. 43, it is seen that in the acoustic wave device according to the ninth example embodiment, in a case where the average inter-electrode pitch change rate pr_{A} is about 0.006 and the inter-electrode pitch change rates pr_{L} and pr_{R} are about-0.008 or less or about 0.008 or more, an improvement is made regarding the phase drop at about 5102 MHz as compared to the acoustic wave devices according to the comparative examples 1 and 2. Thus, for example, the structure in which the absolute values of the ratios of the inter-electrode pitch change rates pr_{L} and pr_{R} to the average inter-electrode pitch change rate pr_{A} (|pr_{L}/pr_{A}| and |pr_{R}/pr_{A}|) are set to about 1.33 (=0.008/0.006) or more can reduce or prevent the influence of the leaky wave L shown in FIG. 42 on the impedance phase of the acoustic wave device.

The foregoing description of the ninth example embodiment is provided based on the structure in which the inter-electrode pitch between the first electrode finger 31a and the second electrode finger 32b is equal or substantially equal to the inter-electrode pitch pr and the inter-electrode pitch between the fourth electrode finger 31b and the third electrode finger 32a is equal or substantially equal to the inter-electrode pitch p_{R}. However, the inter-electrode pitch between the first electrode finger 31a and the second electrode finger 32b may be different from the inter-electrode pitch pr and/or the inter-electrode pitch between the fourth electrode finger 31b and the third electrode finger 32a may be different from the inter-electrode pitch p_{R}.

The foregoing description of the ninth example embodiment is provided based on the case where the ratio pr_{L}/pr_{A} between the inter-electrode pitch change rates is equal or substantially equal to the ratio pr_{R}/pr_{A} between the inter-electrode pitch change rates, but the ratio pr_{L}/pr_{A} between the inter-electrode pitch change rates and the ratio pr_{R}/pr_{A} between the inter-electrode pitch change rates may have different values. In this case, if at least one of the absolute values |pr_{L}/pr_{A}| and |pr_{R}/pr_{A}| of the ratios between the inter-electrode pitch change rates is, for example, about 1.33 or more, it is possible to reduce or prevent the influence of the leaky wave L on the impedance phase of the acoustic wave device described above.

The relationship among the inter-electrode pitches in the ninth example embodiment described above may be combined with any of the foregoing example embodiments and modifications.

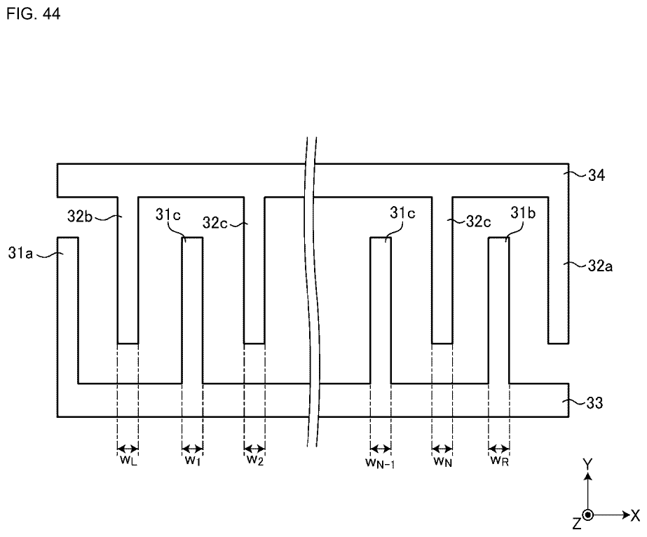

FIG. 44 is a plan view illustrating an IDT electrode of an acoustic wave device according to a tenth example embodiment of the present invention. Here, as in the ninth example embodiment, the number of central electrode fingers 31c and 32c is denoted as N.

The tenth example embodiment will be described, as illustrated in FIG. 44, where wₙ denotes an electrode width of an n-th central electrode finger 31c or 32c (n is an integer of 1 or more to N or less) counted in the X direction from the electrode finger adjacent to the second electrode finger 32b among the central electrode fingers, w_{L} denotes an electrode width of the electrode finger externally adjacent to, in the arrangement direction, the first electrode finger counted in the X direction, i.e., the second electrode finger 32b, and w_{R} denotes an electrode width of the electrode finger externally adjacent to an N-th electrode finger in the arrangement direction, i.e., the fourth electrode finger 31b. In this case, electrode width change rates wrₙ, wr_{L}, and wr_{R} are defined as values expressed by Formulas (8) to (10) below, respectively. In addition, an arithmetic mean of the electrode width change rates wrₙ expressed by Formula (11) below is referred to as an average electrode width change rate wr_{A}. In the present disclosure, the average change rate of a dimension (electrode width) of each of the central electrode fingers 31c and 32c in the direction orthogonal to the extension direction of the multiple electrode fingers refers to the average electrode width change rate wr_{A}, and the electrode width change rate of a dimension (electrode width), in the direction orthogonal to the extension direction of the multiple electrode fingers, of an electrode finger (the fourth electrode finger 31b or the second electrode finger 32b) externally adjacent to the central electrode finger 31c or 32c in the arrangement direction (X direction) refers to at least one of the electrode width change rates wr_{L} and wr_{R}:

$${wr}_{n} = \vert ( {w}_{n + 1} - {w}_{n} ) / {w}_{n} \vert \qquad Formula ( 8 )$$

$${wr}_{L} = ( {w}_{1} - {w}_{L} ) / {w}_{L} \qquad Formula ( 9 )$$

$${wr}_{R} = ( {w}_{N} - {w}_{R} ) / {w}_{R} \qquad Formula ( 10 )$$

$$\begin{matrix}Formula 2 & \\ {wr}_{A} = \frac{1}{N} {\sum }_{k = 1}^{N} {wr}_{k} & Formula ( 11 )\end{matrix}$$

In the tenth example embodiment, the electrode width change rates wr_{L} and wr_{R} are made different from the average electrode width change rate wr_{A}. In the acoustic wave device according to the tenth example embodiment, the electrode widths of the first electrode finger 31a and the second electrode finger 32b are equal or substantially equal to each other. Here, the electrode width of the first electrode finger 31a is equal or substantially equal to the electrode width w_{L} and the electrode width of the third electrode finger 32a is equal or substantially equal to the electrode width w_{R}.

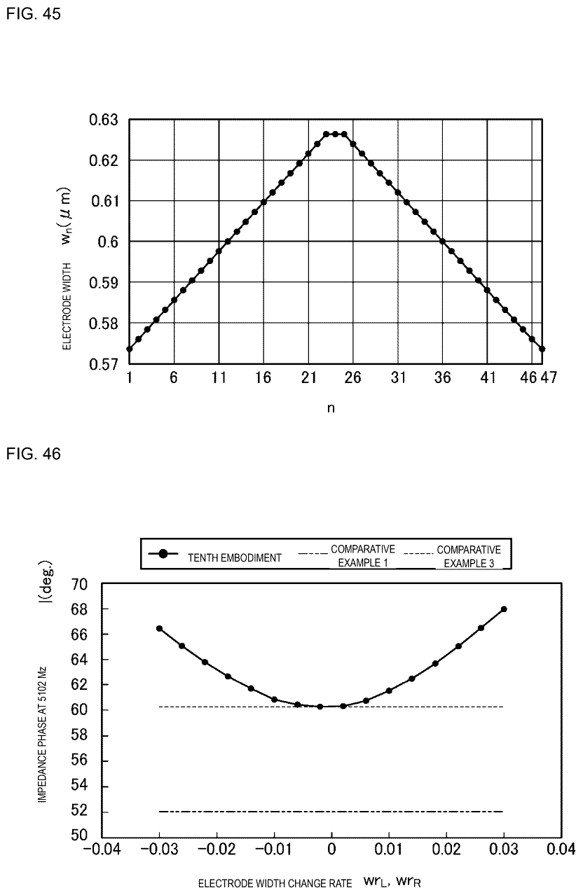

FIG. 45 is an explanatory diagram showing the electrode widths wₙ in the acoustic wave device according to the tenth example embodiment. In the tenth example embodiment, the total number of the electrode fingers 31 and the electrode fingers 32 in the IDT electrode 30 is, for example, 51. In other words, in the tenth example embodiment, N is equal to, for example, 47. As shown in FIG. 45, in the acoustic wave device according to the tenth example embodiment, the electrode widths wₙ increase as n increments from n=1 to n (n=23) closest to (N+1)/2, are maximized at n (n=23, 24, 25) closest to (N+1)/2, and then decrease as n increments from n (n=25) closest to (N+1)/2 to n=N (n=47). In sum, according to the tenth example embodiment, the electrode widths wₙ of the central electrode fingers 31c and 32c increase toward the center among the central electrode fingers. Here, the average electrode width change rate wr_{A} according to the tenth example embodiment is, for example, about 0.004. In addition, the average electrode width of the central electrode fingers 31c and 32c according to the tenth example embodiment is, for example, about 0.6 μm.

In the acoustic wave device according to the tenth example embodiment, the inter-electrode pitches between the first electrode finger 31a, the second electrode finger 32b, the third electrode finger 32a, the fourth electrode finger 31b, and the central electrode fingers 31c and 32c and the respective electrode fingers internally adjacent to them in the arrangement direction are equal or substantially equal to each other. The inter-electrode pitches between the first electrode finger 31a, the second electrode finger 32b, the third electrode finger 32a, the fourth electrode finger 31b, and the central electrode fingers 31c and 32c and the respective electrode fingers internally adjacent to them are, for example, about 2.38 μm.

In addition, in the tenth example embodiment, the electrode structure of the IDT electrode 30 is, for example, a multilayer film of Ti/AlCu/Ti/AlCu stacked from the piezoelectric layer 20 side, and their respective film thicknesses are about 12 nm/about 70 nm/about 18 nm/about 12 nm. The structures of the first protective film 41 and so on are the same or substantially the same as those in the first example embodiment. Specifically, the film thickness of the piezoelectric layer 20 is, for example, about 181 nm. The film thickness of the first protective film 41 is, for example, about 142 nm. The film thickness of the second protective film 42 is, for example, about 142 nm.

A comparative example 1 has a structure including the electrode fingers 31 and 32 all having equal or substantially equal electrode widths and equal or substantially equal inter-electrode pitches, unlike the acoustic wave device according to the tenth example embodiment. This comparative example 1 has the same or substantially the same structure as in the comparative example 1 described according to FIG. 42 in the ninth example embodiment.

A comparative example 3 has the same or substantially the same structure as in the acoustic wave device according to the tenth example embodiment except that the electrode width change rates wr_{L} and wr_{R} are set to 0, i.e., the electrode width w_{L} is equalized to w₁ and the electrode width w_{R} is equalized to w_{N}.

FIG. 46 is an explanatory diagram showing impedance phases at about 5102 MHz in the acoustic wave devices according to the tenth example embodiment and the comparative examples 1 and 3. As shown in FIG. 46, it is seen that in the acoustic wave device according to the tenth example embodiment, in a case where the average electrode width change rate wr_{A} is about 0.004 and the electrode width change rates wr_{L} and wr_{R} are about −0.01 or less or about 0.01 or more, an improvement is made concerning the phase drop at about 5102 MHz as compared to the acoustic wave devices according to the comparative examples 1 and 3. Thus, the structure in which the absolute values of the ratios (|wr_{L}/wr_{A}| and |wr_{R}/wr_{A}|) of the electrode width change rates wr_{L} and wr_{R} to the average electrode width change rate wr_{A} are set to, for example, about 2.5 (=0.01/0.004) or more can reduce or prevent the influence of the leaky wave L shown in FIG. 42 on the impedance phase of the acoustic wave device.

The foregoing description of the tenth example embodiment is provided based on the structure in which the electrode width of the first electrode finger 31a is equal or substantially equal to the electrode width w_{L} and the electrode width of the third electrode finger 32a is equal or substantially equal to the electrode width w_{R}. However, the electrode width of the first electrode finger 31a may be different from the electrode width w_{L} and/or the electrode width of the third electrode finger 32a may be different from the electrode width w_{R}.

The foregoing description of the tenth example embodiment is provided based on the case in which the ratio wr_{L}/wr_{A} between the electrode width change rates is equal or substantially equal to the ratio wr_{R}/wr_{A} between the electrode width change rates, but the ratio wr_{L}/wr_{A} between the electrode width change rates and the ratio wr_{R}/wr_{A} between the electrode width change rates may have different values. In this case, if at least one of the absolute values |wr_{L}/wr_{A}| and |wr_{R}/wr_{A}| of the ratios between the electrode width change rates is, for example, about 2.5 or more, it is possible to reduce or prevent the influence of the leaky wave L on the impedance phase of the acoustic wave device described above.

The relationship among the electrode widths in the tenth example embodiment described above may be combined with any of the foregoing example embodiments and modifications.

The shapes, widths, film thicknesses, and so on of the first protective film 41 and the IDT electrode 30 are merely examples, and may be changed as appropriate. For example, the side surfaces of the IDT electrode 30 may have a tapered shape. The electrode fingers 31 and 32 illustrated in FIG. 1 may have the same or substantially the same film thickness. Instead, the electrode fingers 31 and 32 may have different film thicknesses due to, for example, variations in the manufacture process. In addition, the central electrode fingers 31c and 32c illustrated in FIG. 2 may have the same or substantially the same width. Instead, the central electrode fingers 31c and 32c may have different widths due to, for example, variations in the manufacture process.

In the foregoing example embodiments and modifications, the structure is described in which the electrode width of one or two electrode fingers 31 and 32 located in the outermost portion is different from the electrode width of the other electrode fingers 31 and 32, but the structure is not limited to this. Another structure is possible in which the electrode width of at least one of three electrode fingers 31 and 32 located in the outermost portion in the arrangement direction of the multiple electrode fingers 31 and 32 is different from the electrode width of the other electrode fingers 31 and 32 located in the central portion. Similarly, another structure is possible in which the inter-electrode pitch P between at least one of three electrode fingers 31 and 32 located in the outermost portion in the arrangement direction of the multiple electrode fingers 31 and 32 and the electrode finger internally adjacent to the at least one electrode finger in the arrangement direction of the multiple electrode fingers 31 and 32 is different from the inter-electrode pitch P between the other electrode fingers 31 and 32 located in the central portion.

Moreover, in a structure in which the electrode widths of all of the multiple electrode fingers 31 and 32 are the same or substantially the same and the inter-electrode pitches P between all of the central electrode fingers 31c and 32c are the same or substantially the same, the inter-electrode pitch P between at least one of one or two electrode fingers 31 and 32 located in the outermost portion and the electrode finger internally adjacent to that electrode finger in the arrangement direction of the multiple electrode fingers 31 and 32 may be different from the inter-electrode pitches P between the other electrode fingers 31 and 32 located in the central portion.

Furthermore, in a structure in which all of the inter-electrode pitches P between all of the multiple electrode fingers 31 and 32 are the same or substantially the same and the electrode widths of all of the other electrode fingers 31 and 32 located in the central portion are the same or substantially the same, the electrode width of at least one of one or two electrode fingers 31 and 32 located in the outermost portion may be different from the electrode widths of the other electrode fingers 31 and 32 located in the central portion.

The example embodiments and modifications described above are intended to facilitate understanding of the present invention and are not intended to limit the interpretation of the present invention. The present invention may be modified or improved without departing from the gist and scope of the present invention, and the present invention includes its equivalents.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface opposed to the first main surface;
an interdigital transducer (IDT) electrode on at least one of the first main surface and the second main surface of the piezoelectric layer and including a plurality of electrode fingers arranged in a predetermined direction; and
a support facing the second main surface of the piezoelectric layer and including an acoustic reflection portion toward the second main surface of the piezoelectric layer; wherein
at least one of a first electrode finger located in an outermost portion in an arrangement direction of the plurality of electrode fingers among the plurality of electrode fingers and a second electrode finger internally adjacent to the first electrode finger in the arrangement direction differs from central electrode fingers arranged inside the second electrode finger in the arrangement direction in at least one of a dimension in a direction orthogonal or substantially orthogonal to an extension direction of the plurality of electrode fingers and an inter-center distance to an internally adjacent electrode finger in the arrangement direction; and
d/p is about 0.5 or less, where d denotes a thickness of the piezoelectric layer and p denotes the inter-center distance between the adjacent electrode fingers.

2. The acoustic wave device according to claim 1, further comprising a protective film on at least one of the first main surface and the second main surface of the piezoelectric layer.

3. The acoustic wave device according to claim 1, wherein the first electrode finger differs from the central electrode fingers in at least one of the dimension in the direction orthogonal or substantially orthogonal to the extension direction of the plurality of electrode fingers and the inter-center distance to the internally adjacent electrode finger in the arrangement direction.

4. The acoustic wave device according to claim 1, wherein the second electrode finger differs from the central electrode fingers in at least one of the dimension in the direction orthogonal or substantially orthogonal to the extension direction of the plurality of electrode fingers and the inter-center distance to the internally adjacent electrode finger in the arrangement direction.

5. The acoustic wave device according to claim 1, wherein at least one of the first electrode finger and the second electrode finger is smaller than the central electrode fingers in at least one of the dimension in the direction orthogonal or substantially orthogonal to the extension direction of the plurality of electrode fingers and the inter-center distance to the internally adjacent electrode finger in the arrangement direction.

6. The acoustic wave device according to claim 1, wherein at least one of the first electrode finger and the second electrode finger is larger than the central electrode fingers in at least one of the dimension in the direction orthogonal to the extension direction of the plurality of electrode fingers and the inter-center distance to the internally adjacent electrode finger in the arrangement direction.

7. The acoustic wave device according to claim 1, wherein
the first electrode finger, the second electrode finger, and the central electrode fingers are equal or substantially equal to each other in the dimension in the direction orthogonal or substantially orthogonal to the extension direction of the plurality of electrode fingers; and
at least one of the first electrode finger and the second electrode finger is larger than the central electrode fingers in the inter-center distance to the internally adjacent electrode finger in the arrangement direction.

8. The acoustic wave device according to claim 1, wherein
the first electrode finger, the second electrode finger, and the central electrode fingers are equal or substantially equal to each other in the dimension in the direction orthogonal or substantially orthogonal to the extension direction of the plurality of electrode fingers;
the central electrode fingers are equal to each other in the inter-center distance to the internally adjacent electrode finger in the arrangement direction; and
at least one of the first electrode finger and the second electrode finger differs from the central electrode fingers in the inter-center distance to the internally adjacent electrode finger in the arrangement direction.

9. The acoustic wave device according to claim 1, wherein
the first electrode finger, the second electrode finger, and the central electrode fingers are equal or substantially equal to each other in the dimension in the direction orthogonal or substantially orthogonal to the extension direction of the plurality of electrode fingers;
the central electrode fingers differ from each other in the inter-center distance to the internally adjacent electrode finger in the arrangement direction;
the first electrode finger and the second electrode finger differ from the central electrode fingers in the inter-center distance to the internally adjacent electrode finger in the arrangement direction; and
an absolute value of a ratio of an inter-electrode pitch change rate of an electrode finger externally adjacent to the central electrode fingers in the arrangement direction to an average inter-electrode pitch change rate of the central electrode fingers is about 1.33 or more.

10. The acoustic wave device according to claim 1, wherein
the first electrode finger, the second electrode finger, and the central electrode fingers are equal or substantially equal to each other in the inter-center distance to the internally adjacent electrode finger in the arrangement direction;
the central electrode fingers are equal or substantially equal to each other in the dimension in the direction orthogonal or substantially equal to the extension direction of the plurality of electrode fingers; and
at least one of the first electrode finger and the second electrode finger differs from the central electrode fingers in the dimension in the direction orthogonal or substantially orthogonal to the extension direction of the plurality of electrode fingers.

11. The acoustic wave device according to claim 1, wherein
the first electrode finger, the second electrode finger, and the central electrode fingers are equal or substantially equal to each other in the inter-center distance to the internally adjacent electrode finger in the arrangement direction;
the central electrode fingers differ from each other in the dimension in the direction orthogonal or substantially orthogonal to the extension direction of the plurality of electrode fingers;
at least one of the first electrode finger and the second electrode finger differs from the central electrode fingers in the dimension in the direction orthogonal to the extension direction of the plurality of electrode fingers; and
an absolute value of a ratio of a change rate of the dimension in the direction orthogonal or substantially orthogonal to the extension direction of the plurality of electrode fingers of an electrode finger externally adjacent to the central electrode fingers in the arrangement direction to an average change rate of the dimension in the direction orthogonal to the extension direction of the plurality of electrode fingers of the central electrode fingers is about 2.5 or more.

12. The acoustic wave device according to claim 1, further comprising a load film in a region overlapping the first electrode finger located in the outermost portion in the arrangement direction of the plurality of electrode fingers among the plurality of electrode fingers.

13. The acoustic wave device according to claim 12, wherein at least one of carbon-doped silicon oxide, silicon oxide, silicon nitride, tantalum pentoxide, aluminum nitride, aluminum oxide, hafnium oxide, niobium pentoxide, and tungsten oxide is included in the load film.

14. The acoustic wave device according to claim 1, further comprising:
a protective film on at least one of the first main surface and the second main surface of the piezoelectric layer; wherein
the protective film includes silicon oxide.

15. The acoustic wave device according to claim 1, wherein
the IDT electrode is provided on both of the first main surface and the second main surface of the piezoelectric layer.

16. An acoustic wave filter apparatus comprising at least one resonator including the acoustic wave device according to claim 1.

17. The acoustic wave filter apparatus according to claim 16, further comprising:
an input terminal;
an output terminal;
a series arm coupled to the input terminal and the output terminal; and
a parallel arm coupled a node of the series arm and a ground; wherein
the at least one resonator includes a plurality of resonators, and includes a series arm resonator at the series arm and a parallel arm resonator at the parallel arm; and
a plurality of electrode fingers of the series arm resonator and a plurality of electrode fingers of the parallel arm resonator have different structures.

18. The acoustic wave device according to claim 1, wherein the piezoelectric layer includes lithium niobate or lithium tantalate and is 120°±10° rotated Y-cut or 90°±10° rotated Y-cut.

19. The acoustic wave device according to claim 1, further comprising:
a protective film on at least one of the first main surface and the second main surface of the piezoelectric layer; wherein
the protective film includes a first protective film on the first main surface of the piezoelectric layer and covering the IDT electrode, and a second protective film on the second main surface of the piezoelectric layer.

20. The acoustic wave device according to claim 19, wherein a value A/B is about 1−0.06 or more and about 1+0.06 or less, where A denotes a total distance from a center of a film thickness of the piezoelectric layer to a top surface of the first protective film, and B denotes a total distance from the center of the film thickness of the piezoelectric layer to a top surface of the second protective film.

21. The acoustic wave device according to claim 19, wherein an upper surface of the first protective film and a lower surface of the second protective film are flat.

22. The acoustic wave device according to claim 1, further comprising:
a protective film on at least one of the first main surface and the second main surface of the piezoelectric layer; wherein
a film thickness of the protective film is smaller than a film thickness of the IDT electrode.

23. The acoustic wave device according to claim 1, further comprising:
a protective film on at least one of the first main surface and the second main surface of the piezoelectric layer; wherein
a film thickness of the protective film is larger than a film thickness of the IDT electrode.

24. The acoustic wave device according to claim 1, wherein d/p is about 0.24 or less.

25. The acoustic wave device according to claim 1, wherein
an excitation region is defined as a region where adjacent electrode fingers of the plurality of electrode fingers overlap each other as viewed from the direction orthogonal or substantially orthogonal to the plurality of electrode fingers, the region being located between centers of the adjacent electrode fingers in the direction orthogonal or substantially orthogonal to the electrode fingers; and
MR≤about 1.75 (d/p)+0.075 is satisfied, where MR denotes a metallization ratio of the electrode fingers to the excitation region.

26. The acoustic wave device according to claim 1, wherein the piezoelectric layer includes lithium tantalate or lithium niobate.

27. The acoustic wave device according to claim 26, wherein Euler angles (φ, θ, ψ) of the lithium niobate or the lithium tantalate of the piezoelectric layer are within a range of any of Formulas (1), (2) or (3):
$$( 0 ° \pm 10 ° , 0 ° to 20 ° , and ψ ) ; \qquad Formula ( 1 )$$
$$( 0 ° \pm 10 ° , 20 ° to 80 ° , 0 ° to 60 ° {( 1 - {( θ - 50 )}^{2} / 900 )}^{1 / 2} ) or$$
$$Formula ( 2 )$$
$$( 0 ° \pm 10 ° , 20 ° to 80 ° , [ 180 ° - 60 ° {( 1 - {( θ - 50 )}^{2} / 900 )}^{1 / 2} ] to 180 ° ) ;$$
$$and$$
$$Formula ( 3 )$$
$$( 0 ° \pm 10 ° , [ 180 ° - 30 ° {( 1 - {( ψ - 90 )}^{2} / 8100 )}^{1 / 2} ] to 180 ° , any ψ ) .$$

28. The acoustic wave device according to claim 1, wherein
the acoustic reflection portion includes a hollow portion; and
the support and the piezoelectric layer are arranged such that a portion of the support and a portion of the piezoelectric layer face each other across the hollow portion.

29. The acoustic wave device according to claim 1, wherein
the acoustic reflection portion includes an acoustic reflection film including a high acoustic impedance layer having a relatively high acoustic impedance and a low acoustic impedance layer having a relatively low acoustic impedance; and
the support and the piezoelectric layer are arranged such that at least a portion of the support and at least a portion of the piezoelectric layer face each other across the acoustic reflection film.
